(19) United States
(12) Patent Application Publication
(10) Pub. No.: US 2013/0260560 A1
(43) Pub. Date: Oct. 3, 2013

(54) Patterning Processes Comprising Amplified Patterns

(71) Applicant: Nano Terra Inc., Brighton, MA (US)

(72) Inventors: Brian T. MAYERS, Somerville, MA (US); Jeffrey CARBECK, Belmont, MA (US); Wajeeh SAADI, Cambridge, MA (US); George M. WHITESIDES, Newton, MA (US)

(21) Appl. No.: 13/905,675

(22) Filed: May 30, 2013

Related U.S. Application Data
(63) Continuation of application No. 12/493,757, filed on Jun. 29, 2009, now abandoned.
(60) Provisional application No. 61/076,154, filed on Jun. 27, 2008.

(51) Int. Cl. B05D 5/00; H01L 21/306

(52) U.S. Cl. CPC B05D 5/00; H01L 21/306
USPC 438/694; 427/282; 216/47; 427/558; 205/136; 134/2; 134/18

(57) ABSTRACT

The present invention is directed to substrates comprising amplified patterns, methods for making the amplified patterns, and methods of using the amplified patterns to form surface features on the substrates.

### CROSS-REFERENCE TO RELATED APPLICATIONS

This application claims the benefit of the filing date of U.S. Patent Application No. 61/076,154, filed Jun. 27, 2008, which is incorporated by reference herein in its entirety.

### BACKGROUND OF THE INVENTION

1. Field of the. Invention

The present invention is directed to methods for patterning a surface using contact printing processes that employ a stamp or an elastomeric stencil and a paste.

2. Background

Methods of patterning surfaces are well known and include photolithography techniques, as well as the more recently developed soft-contact printing techniques such as “micro-contact printing” (see, e.g., U.S. Pat. No. 5,512,131).

Traditional photolithography methods, while versatile in the architectures and compositions of surface features to be formed, are also costly and require specialized equipment. Moreover, photolithography techniques have difficulty patterning very large and/or non-rigid surfaces such as, for example, textiles, paper, plastics, and the like.

Soft-lithographic techniques have demonstrated the ability to produce surface features having lateral dimension as small as 40 nm or less in a cost-effective, reproducible manner. Patterns formed by soft-lithographic techniques often rely upon the formation of self-assembled monolayers (“SAMs”), which can contain many defects when the surface is of a large area or is non-rigid, rough, or wavy.

What is needed is a soft-lithographic patterning method that can produce robust patterns on surface having a large area, and/or surfaces that are non-rigid, rough, or wavy.

### BRIEF SUMMARY OF THE INVENTION

The present invention is directed to substrates comprising amplified patterns, methods for making the amplified patterns, and methods of using the amplified patterns to form surface features on the substrates. In some embodiments, the present invention is directed to methods for forming a pattern on a substrate using a contact-printing technique, and then amplifying the pattern by disposing a composition onto the pattern. In some embodiments, the present invention is directed to amplifying a pattern on a substrate comprising a self-assembled monolayer that contains point or grain boundary defects by disposing onto the pattern a composition that preferentially wets the pattern. The resulting amplified pattern can be used as a mask to define surface features on a substrate. The amplified patterns of the present invention exhibit improved robustness and chemical resistance during subsequent process steps. Surface features formed using the amplified patterns include at least one lateral dimension of about 100 μm or less. The present invention permits all varieties of surfaces to be patterned in a cost-effective, efficient, and reproducible manner.

The present invention is directed to a process for patterning a substrate, the process comprising:
(a) providing an unmasked substrate;
(b) depositing onto the unmasked substrate a pattern comprising a first material having a first surface characteristic, wherein the pattern substantially covers a first area of the unmasked substrate;
(c) disposing onto the substrate a composition having a functional group suitable for associating with the surface of the pattern, wherein the composition deposits preferentially onto the pattern to farm an amplified pattern, and wherein an area of the substrate not covered by the pattern its substantially free from the composition; and
(d) reacting, the area of the substrate not covered by the amplified pattern, wherein the first area of the substrate covered by the amplified pattern is substantially not reacted.

The present invention is also directed to a process for increasing the reaction selectivity between a pattern area of a substrate and an unpatterned area of a substrate, the process comprising:
(a) providing a substrate having a pattern formed thereon, wherein the pattern comprises a material having a first surface characteristic, wherein the pattern substantially covers a first area of the substrate;
(b) disposing onto the substrate a composition that deposits preferentially on the pattern via a covalent bonding interaction to form an amplified pattern, wherein an area of the substrate not covered by the pattern is substantially free from the composition, wherein the area of the substrate covered by the amplified pattern has a reactivity with a reactant that is at least three times less than the reactivity of an area of the substrate having the unamplified pattern thereon; and
(c) reacting the area of the substrate not covered by the pattern to form a surface feature thereon.

In some embodiments, the area of the substrate not covered by the pattern reacts at least about five times fluster than the area of the substrate covered by the amplified pattern.

In some embodiments, the process of the present invention further comprises after the depositing and/or providing and prior to the disposing: disposing onto the substrate a second material having a hydrophilic surface characteristic, wherein the second composition deposits preferentially on an area of the substrate not covered by the pattern.

In some embodiments, the process further comprises prior to the reacting: depositing onto the substrate a second pattern comprising a second material having a second surface characteristic, wherein the second surface characteristic is different from the first surface characteristic of the first material, and wherein the second pattern substantially covers a second area of the substrate.

In some embodiments, the process further comprises after the disposing of a first material: disposing onto the substrate as second material having a second surface characteristic that is different from the first surface characteristic, wherein the second composition deposits preferentially on an area of the substrate not covered by the pattern.

In some embodiments, the reacting comprises at least one of: wet etching, dry etching, electroplating, cleaning, chemically oxidizing, chemically reducing, exposing to ultraviolet light, and combinations thereof. In some embodiments, the reacting comprises wet etching.

In some embodiments, the process further comprises after the disposing: solidifying the masking pattern.

In some embodiments, the process further comprises after the reacting: removing the masking pattern from the substrate.

In some embodiments, the providing comprises providing a substrate selected from: a metal, a metal oxide, a glass, a semiconductor, a plastic, a laminate thereof, and combinations thereof.

In some embodiments, the depositing further comprises depositing a pattern comprising a self-assembled monolayer. In some embodiments, the depositing further comprises depositing a pattern comprising a self-assembled monolayer by a microcontact printing process. In some embodiments, the depositing further comprises depositing a first self-assembled monolayer having a hydrophobic surface characteristic.

The present invention is also directed to a patterned substrate prepared by the above processes.

The present invention is also directed to an amplified, pattern prepared by a contact printing process, the process comprising:
(a) providing a substrate;
(b) contact printing onto a first area of the substrate a pattern comprising a material having a first surface characteristic;
(c) disposing onto the substrate a composition that deposits preferentially onto the pattern to form an amplified pattern, wherein an area of the substrate not covered by the pattern is substantially free from the composition, and wherein the amplified pattern has a reactivity with at least one of a chemical etchant, a chemical oxidant, an ionic metal, and ultraviolet light, that is at least three times less than the reactivity of the pattern comprising the material.

In some embodiments, the contact printing further comprises contact printing a pattern comprising a self-assembled monolayer.

The present invention is also directed to an apparatus for patterning an unmasked substrate, the apparatus comprising:
(a) a means for preferentially depositing a composition onto an unmasked patterned substrate; and
(b) a means for reacting an area of the unmasked substrate substantially not covered by the pattern or the composition deposited thereon.

In some embodiments, the apparatus further comprises: a means for depositing onto the unmasked substrate a pattern comprising a self-assembled monolayer.

In some embodiments, the apparatus further comprises: a means fir providing the unmasked substrate; a means for transferring the unmasked substrate between the means for depositing the pattern and the means for reacting; and a means for collecting the unmasked substrate after reacting an area of the substrate.

The present invention is also directed to a patterned substrate comprising:
(a) a first area of the substrate having a pattern thereon, the pattern comprising:
   (i) a first layer contacting the substrate, wherein the first layer comprises a material having a first surface characteristic; and
   (ii) a second layer contacting the first layer, wherein the second layer comprises a composition having a second surface characteristic, wherein the second surface characteristic has an affinity to the first surface characteristic of the first layer; and
(b) a second area of the substrate having a feature thereon, wherein the feature is not present on the first area of the substrate, and wherein the feature has a surface characteristic incompatible with the surface characteristics of the first and the second layers.

In some embodiments, the first layer of the patterned substrate comprises a self-assembled monolayer.

In some embodiments, the second layer of the patterned substrate has a thickness of at least about 50 times the thickness of the first layer.

In some embodiments, the pattern of the patterned substrate is substantially free of solvent.

In some embodiments, the feature on the patterned substrate comprises a feature selected from: an additive non penetrating surface feature, an additive penetrating surface feature, a conformal non penetrating surface feature, a conformal penetrating surface feature, a subtractive non penetrating surface feature, a subtractive penetrating surface feature, and combinations thereof.

Further embodiments, features, and advantages of the present inventions, as well as the structure and operation of the various embodiments of the present invention, are described in detail below with reference to the accompanying drawings.

### BRIEF DESCRIPTION OF THE DRAWINGS

The accompanying drawings, which arc incorporated herein and form a part of the specification, illustrate one or more embodiments of the present invention and, together with the description, further serve to explain the principles of the invention and to enable a person skilled in the pertinent art to make and use the invention.

FIGS. 1A, 1B, 1C, 1D, 1E, 1F and 1G provide schematic cross-sectional representations of surfaces having surface features thereon that can be prepared by a method of the present invention.

FIG. 2 provides a schematic cross-sectional representation of a curved surface having surface features thereon that can be prepared by a method of the present invention.

FIGS. 3A, 3B, 3C, 3D, 3E, 3F and 3G provide schematic cross-sectional representations of a process of the present invention.

FIGS. 4A and 4B provide schematic cross-sectional representations of an embodiment of a process step of the present invention.

FIGS. 5A, 5B and 5C provide microscope images of amplified patterns prepared by a process of the present invention. FIG. 5B and FIG. 5C provide higher magnification images of the pattern in FIG. 5A.

FIG. 6 provides a microscope image of a substrate containing an unamplified pattern thereon after exposure to a wet etching solution.

FIG. 7 provides a microscope image of a substrate containing an unamplified pattern thereon after exposure to a wet etching solution.

FIGS. 8A, 8B provide transmissive and DIC microscope images, respectively, of a substrate containing an amplified pattern thereon after exposure to a wet etching solution.

FIGS. 9A, 9B, 9C, 9D and 9E provide transmissive and DIC microscope images of a substrate containing an amplified pattern thereon after exposure to a wet etching solution. FIGS. 9C, 9D and 9E provide higher magnification images of the pattern in FIGS. 9A and 9B.

One or more embodiments of the present invention will now be described with reference to the accompanying drawings. In the drawings, like reference numbers can indicate identical or functionally similar elements. Additionally, the left-most digit(s) of a reference number can identify the drawing in which the reference number First appears.

### DETAILED DESCRIPTION OF INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

References to spatial descriptions (e.g., “above”, “below”, “up”, “down”, “top”, “bottom,” etc.) made herein are for purposes of description and illustration only, and should be interpreted as non-limiting upon the processes, substrates, patterns, and/or products of any process of the present invention, which can be spatially arranged in any orientation or manner.

### Substrates

The present invention provides methods for forming a feature in or on a surface of a substrate. Substrates suitable for use with the present invention are not particularly limited by size, composition or geometry. For example, the present invention is suitable for patterning planar, curved, symmetric, and asymmetric objects and surfaces, and any combination thereof. Additionally, the substrate surface can be homogeneous or heterogeneous in composition. The processes are also not limited by surface roughness or surface waviness, and are equally applicable to smooth, rough and wavy surfaces, and substrates exhibiting heterogeneous surface morphology (i.e., substrates having varying degrees of smoothness, roughness and/or waviness).

Substrates suitable for patterning by a process of the present invention are not particularly limited by composition, and include, but are not limited to, metals, alloys, composites, crystalline materials, amorphous materials, conductors, semiconductors, optics, fibers, glasses, ceramics, zeolites, plastics, films, thin films, foils, plastics, polymers, minerals, biomaterials, living tissue, bone, alloys thereof, laminates thereof, and combinations thereof. In some embodiments, a substrate is selected from a porous variant of any of the above materials, wherein the pore diameter (i.e., the mean free path of the pores) in the material is about 5 Å to about 50 nm, about 6 Å to about 20 nm, or about 7 Å to about 5 nm.

In some embodiments, a substrate to be patterned by a process of the present invention comprises a metal. In some embodiments, a metal is selected from: a transition metal, a Group IIIB metal, a Group IVB metal, and combinations thereof. In some embodiments, a substrate comprises a metal selected from: titanium, chromium, iron, cobalt, nickel, copper, zinc, gallium, zirconium, molybdenum, palladium, silver, cadmium, indium, tin, tantalum, tungsten, iridium, platinum, gold, lead, bismuth, alloys thereof doped variants thereof, and combinations thereof.

In some embodiments, a substrate to be patterned by a process of the present invention comprises a semiconductor such as, but not limited to: crystalline silicon, polycrystalline silicon, amorphous silicon, p-doped silicon, n-doped silicon, silicon oxide, silicon germanium, germanium, gallium arsenide, gallium arsenide phosphide, indium tin oxide, zinc oxide, copper indium selenide, copper-indium-gallium selenide, a doped variant thereof, alloys thereof, and combinations thereof.

In some embodiments, a substrate to be patterned by a process of the present invention comprises a glass such as, but not limited to, undoped silica glass (SiO₂), fluorinated silica glass, borosilicate glass, borophosphorosificate glass, organosilicate glass, porous organosilicate glass, and combinations thereof.

In some embodiments, a substrate to be patterned by a process of the present invention comprises a crystalline material such as, but not limited to, zinc oxide, lead oxide, indium tin oxide, cadmium telluride, and the like, and combinations thereof.

In some embodiments, the substrate comprises a ceramic such as, but not limited to, zinc sulfide (ZnSₓ), boron phosphide (BPₓ), gallium phosphide (GaPₓ), silicon carbide (SiCₓ), hydrogenated silicon carbide (H:SiCₓ), silicon nitride (SiNₓ), silicon carbonitride (SiCₓN_{y}), silicon oxynitride (SiOₓN_{y}), silicon oxyeathide (SiOₓC_{y}), silicon carbon-oxynitride (SiCₓO_{y}N_{z}), hydrogenated variants thereof, doped variants (e.g., n-doped and p-doped variants) thereof, and combinations thereof (where x, y, and z can vary independently from about 0.1 to about 5, about 0.1 to about 3, about 0.2 to about 2, or about 0.5 to about 1).

In some embodiments, a substrate to be patterned, by a process of the present invention comprises a flexible substrate, such as, but not limited to: a plastic, a metal film, a composite thereof, a laminate thereof, and combinations thereof. Plastic substrates suitable for use with the present invention include, but are not limited to, polyethylene terephthalate, polystyrene, polycarbonate, acrylonitrile butadiene styrene, polyacrylic acids, polyalkylacrylates, polyethylene norbonene, polyethylene naphthalate, and the like, and combinations thereof. In some embodiments, a flexible substrate is patterned by a method of the present invention in a reel-to-reel manner.

In some embodiments, a substrate comprises a glass and/or plastic underlayer having a metal thin film thereon. In some embodiments a metal thin film has a thickness of about 10 nm to about 1 μm, about 20 nm to about 750 nm, about 25 nm to about 500 nm, about 25 nm to about 400 nm, about 50 nm to about 300 nm, or about 50 nm to about 250 nm. In some embodiments, a substrate comprises a gold thin film on glass, a gold thin film on plastic, and the like.

The present invention contemplates optimizing the performance, efficiency, cost, and speed of the process by selecting substrates that are optically transmissive, thermally conductive or insulating, electrically conductive or insulating, and combinations thereof.

In some embodiments, a substrate is transparent to at least one type of radiation suitable for initiating a reaction on the surface of the substrate. For example, a substrate transparent to ultraviolet light can be used in combination, with a UV-sensitive material, thereby permitting a surface feature on the front-surface of a substrate to be initiated by illuminating a back-surface of the substrate with ultraviolet light.

As used herein, an “unmasked substrate” refers to a substrate lacking a material, composition, or pattern suitable for blocking a portion of the substrate from reacting with or becoming patterned by a first material having a first surface characteristic. However, substrates having patterns thereon, and/or topographical features thereon are considered to be within the scope of unmasked substrates suitable for use with the present invention.

The processes of the present invention are particularly suitable for manufacturing environments in which large-area substrates are patterned efficiently (e.g., using a minimum amount of time and materials). In some embodiments, a substrate patterned by a process of the present invention has as surface area of about 400 cm² or greater, about 500 cm² or greater, about 750 cm² or greater, about 1,000 cm² or greater, or about 1,500 cm² or greater.

### Deposition of the First Material

A pattern comprising a first material can be formed on an unmasked substrate by methods including, but not limited to, microcontact printing, screen-printing, stenciling, syringe deposition, inkjet printing, dip-pen nanolithography, and combinations thereof.

In some embodiments, a pattern of the first material is formed on an unmasked substrate by a process of microcontact printing. For example, a first material is applied to an elastomeric stamp having at least one indentation therein that defines a pattern, and the coated elastomeric stamp is contacted with an unmasked substrate. The first material is transferred from the surface of the elastomeric stamp that is in contact with the unmasked substrate.

As used herein, a “stamp” refers to a three-dimensional object having on at least one surface of the stamp an indentation that defines a pattern. Stamps for use with the present invention are not particularly limited by geometry, and can be flat, curved, smooth, rough, wavy, and combinations thereof. In some embodiments, a stamp can have a three dimensional shape suitable for conformally contacting a surface of a material. In some embodiments, a stamp can comprise multiple patterned surfaces that comprise the same, or different patterns. In some embodiments, a stamp comprises a cylinder wherein one or more indentations in the curved face of the cylinder define a pattern. As the cylindrical stamp is rolled across an unmasked substrate, the pattern is repeated. A material can be applied to a cylindrical stamp as it rotates. For stamps having multiple patterned surfaces: cleaning, applying, contacting, removing, and reacting steps can occur simultaneously on the different surfaces of the same stamp.

Stamps for use with the present invention are not particularly limited by materials, and can be prepared from materials such as, but not limited to, glass (e.g., quartz, sapphire, borosilicate glass, and the like), ceramics (e.g., metal carbides, metal nitrides, metal oxides, and the like), plastics, elastomers, metals, and combinations thereof. In sonic embodiments, a stamp for use with the present invention comprises an elastomeric polymer.

As used herein, an “elastomeric stamp” refers to a molded three-dimensional object comprising an elastomeric polymer, and having on at least one surface of the stamp an indentation that defines a pattern. More generally, stamps comprising an elastomeric polymer are referred to as elastomeric stamps. As used herein, an “elastomeric stencil” refers to a molded three dimensional object comprising an elastomeric polymer, and having at least one opening that penetrates through two opposite surfaces of the stencil to form an opening in the surface of the three dimensional object. In some embodiments, an elastomeric stamp or stencil can further comprise a stiff, flexible, porous, or woven backing material suitable for preventing deformation of the stamp or stencil when it is used during processes described herein. Similar to stamps, elastomeric stencils for use with the present invention are not particularly limited by geometry, and can be flat, curved, smooth, rough, wavy, and combinations thereof.

Elastomeric polymers suitable for use with the present invention include, but are not limited to, polydimethylsiloxane polysilsesquioxane, polyisoprene, polybutadiene, polychloroprene, acryloxy elastomers, fluorinated and perfluorinated elastomers (e.g., teflon), and combinations thereof. Other suitable materials and methods to prepare elastomeric stamps suitable for use with the present invention are disclosed in U.S. Pat. Nos. 5,512,131; 5,900,160, 6,180,239 and 6,776,094, and pending U.S. application Ser. Nos. 10/776,427, 12/187,070 and 12/472,331, all of which are incorporated herein by reference in their entirety.

In some embodiments, a contact printing process for use with the present invention can be facilitated by the application of pressure or vacuum to the backside of either or both a stamp, a stencil and a substrate. In some embodiments, the application of pressure or vacuum can ensure that any gases are substantially removed from between the surfaces of a stamp or stencil and the substrate, or can ensure that there is conformal contact between surfaces.

In some embodiments, the depositing occurs in about 1 minute or less, about 45 seconds or less, about 30 seconds or less, about 20 seconds or less, or about 10 seconds or less.

### Patterns and Patterning

The present invention comprises depositing onto an unmasked substrate a pattern comprising a first material having a first surface characteristic. As used herein, a “pattern” refers to a layer comprising a material that covers a substrate in a controlled manner such that desired areas of the substrate remain pattern-free (i.e., free from the material). Patterns formed by a process of the present invention can comprise a self-assembled monolayer, a thin film, a wetted substrate, and combinations thereof.

In some embodiments, the thickness of a pattern comprising a first material having a first surface characteristic is about 5 Å to about 100 Å, about 5 Å to about 75 Å, about 5 Å to about 50 Å, about 5 Å to about 40 Å, about 5 Å to about 30 Å about 5 Å to about 20 Å about 10 Å to about 100 Å, about 10 Å to about 50 Å, about 10 Å to about 25 Å, about 15 Å to about 100 Å, about 15 Å to about 50 Å, or about 15 Å to about 30 Å.

In some embodiments, an amplified pattern produced by a process of the present invention comprises rounded edges (i.e., is substantially lacking corners having edges 90° from one another). As used herein, “rounded” edges refers to patterns and amplified patterns having edges that taper towards one another, or that comprise corners having obtuse angles (i.e., having angles >90°, >100°, or >120° or more. In some embodiments, the formation of patterns having rounded corners can improve the reproducibility of patterns by reducing the defect rate in the pattern amplification step.

In some embodiments, the substrate can be selectively patterned, functionalized, derivatized, textured, or otherwise pre-treated prior to patterning with a first material. As used herein, “pre-treating” refers to chemically or physically modifying a substrate prior to depositing a first material. Pre-treating can include, but is not limited to, cleanup, oxidizing, reducing, derivatizing, functionalizing, exposing a substrate to a reactive gas, plasma, thermal energy, ultraviolet radiation, and combinations thereof. In some embodiments, pre-treating a substrate can increase or decrease the associating interaction between a first material, and a substrate. For example, derivatizing as substrate with a polar functional group (e.g., oxidizing the surface) can promote the wetting of a surface by a hydrophilic first material.

As used herein, a “first material” refers to a material, or a mixture thereof suitable for depositing as a pattern on an unmasked substrate. First materials suitable for use with the present invention include, but are not limited to, molecular species, oligomers, dendrimers, polymers, and combinations thereof. First materials suitable for use with the present invention also include inks, gels, pastes, foams, colloids, adhesives, and the like comprising at least one of: a molecular species, oligomer, dendrimer, polymer, nanoparticle, metal, metal complex, and combinations thereof as described herein.

In some embodiments, the first material includes a molecular species, oligomer, dendrimer, and combinations thereof suitable for forming a self-assembled monolayer on a substrate. In some embodiments, the first material comprises a molecular species, oligomer, or dendrimer suitable for wetting the substrate or depositing a thin film on the substrate. Not being bound by any particular theory, materials suitable for forming a self-assembled monolayer, wetting, or depositing a thin film on a substrate contain at least one functional group suitable for associating with the substrate. As used herein, “association” and “associating with” refer to a chemical interaction that is stable under standard temperature and pressure conditions.

Not being bound by any particular theory, associations can include interactions based upon the formation of at least one of: a chemical bond, a hydrogen bond, an ionic bond, a Van der Waals interaction, physical entanglement, intercalation, a magnetic interaction, and combinations thereof. In some embodiments, an association between a material and a substrate is stable for the duration of the process of the present invention. In some embodiments, an association between a self-assembled monolayer and a substrate can be enhanced, diminished, or broken by altering the temperature and/or pressure, application of electrical current, application of a magnetic field, or by exposure to a chemical reactant.

In some embodiments, an association between a first material and a substrate comprises a covalent bond and/or an ionic bond. In some embodiments, an association between a pattern and a compound preferentially deposited thereon comprises a covalent bond, an ionic interaction, a hydrophobic-hydrophobic interaction, or a combination thereof.

Molecular species suitable for use in a material of the present invention include, but are not limited to, unsubstituted and substituted alkyl, alkenyl, alkynyl, aryl, aralkyl, and heteroaryl species, and combinations thereof. Not being bound by any particular theory, oligomers, dendrimers, polymers, nanoparticles, and metal complexes suitable for use with the present invention can comprise the molecular species described herein, wherein the molecular species is suitably used as a repeat unit in an oligomer, dendrimer, polymer, or nanoparticle, or as a ligand in a metal complex.

As used herein, a “nanoparticle” refers to inorganic (i.e. carbon-free), organic (i.e., carbon-containing), and mixed organic-inorganic materials having a particle size of about 10 nm to about 200 nm. In some embodiments, a nanoparticle compositions can be used alone, or further mixed with molecular species, dendrimers, oligomers, polymers and the like to form gels, mixtures, and colloids suitable fur use with the present invention.

As used herein, a “metal” refers to a Group 1 to Group 12 element, as well as Group 13 to Group 16 elements such as aluminum, gallium, germanium indium, tin, antimony, thallium, lead, bismuth and polonium, and alloys thereof.

As used herein, a “metal complex” refers to a species including at least one metal, wherein the metal is associated with a heteroatom or organic group. In some embodiments, the metal is ionized. Metal complexes suitable for use with the present invention include, but are not limited to, gold citrate, copper sulfate, zinc acetate, and combinations thereof.

A molecular species, oligomer, dendrimer, polymer, nanoparticle, and metal complex suitable for use with the present invention can be functionalized with one of the following groups to facilitate an association with a substrate: hydroxyl, alkoxyl, thiol, alkylthio, silyl, alkylsilyl alkylsilenyl, siloxyl, primary amino, secondary amino, tertiary amino, carbonyl, alkylcarbonyl, aminocarbonyl, carbonylamino, carboxy, and combinations thereof. Additional functional groups suitable for forming self-assembled monolayers are disclosed in U.S. Pat. No. 5,512,131, which is herein incorporated by reference in its entirety.

As used herein, “alkyl,” by itself or as part of another group, refers to straight and branched chain hydrocarbons of up to 60 carbon atoms, such as, but not limited to, octyl, decyl, dodecyl, hexadecyl, and octadecyl.

As used herein, “alkenyl,” by itself or as part of another group, refers to a straight and branched chain hydrocarbons of up to 60 carbon atoms, wherein there is at least one double bond between two of the carbon atoms in the chain, and wherein the double bond can be in either of the cis or trans configurations, including, but not limited to, 2-octenyl, 1-dodecenyl, 1-8-hexadecenyl, 8-hexadecenyl, and 1-octadecenyl.

As used herein, “alkynyl,” by itself or as part of another group, refers to straight and branched chain hydrocarbons of up to 60 carbon atoms, wherein there is at least one triple bond between two of the carbon atoms in the chain, including, but not limited to, 1-octynyl, 2-dodecynyl.

As used herein, “aryl,” by itself or as part of another group, refers to cyclic, fused cyclic, and multi-cyclic aromatic hydrocarbons containing up to 60 carbons in the ring portion. Typical examples include phenyl, naphthyl, anthracenyl, fluorenyl, tetracenyl, pentacenyl, hexacenyl, perylenyl, terylenyl, quaterylenyl, coronenyl, and fullerenyl.

As used herein, “aralkyl” or “arylalkyl,” by itself or as part of another group, refers to alkyl groups as defined above having at least one aryl substituent, such as benzyl, phenylethyl, or 2-naphthylmethyl. Similarly, the term “alkylaryl,” as used herein by itself or as part of another group, refers to an aryl group, as defined above, having an alkyl substituent, as defined above.

As used herein, “heteroaryl,” by itself or as part of another group, refers to cyclic, fused cyclic and multicyclic aromatic groups containing up to 60 atoms in the ring portions, wherein the atoms in the ring(s), in addition to carbon, include at least one heteroatom. The term “heteroatom” is used herein to mean an oxygen atom (“O”), a sulfur atom (“S”) or a nitrogen atom (“N”). Additionally, the term heteroaryl also includes N-oxides of heteroaryl species that containing a nitrogen atom in the ring. Typical examples include pyrrolyl, pyridyl pyridyl N-oxide, thiophenyl, and furanyl.

Any one of the above groups can be further substituted with at least one of the following, substituents: hydroxyl, alkoxyl, thiol, alkylthio, silyl, alkylsilyl, alkylsilenyl, siloxyl, primary amino, secondary amino, tertiary amino, carbonyl, alkylcarbortyl, aminocarbonyl, carbonylamino, carboxy, halo, perhalo, alkylenedioxy, and combinations thereof.

As used herein, “hydroxyl” by itself or as part of another group, refers to an (—OH) moiety.

As used herein, “alkoxyl,” by itself or as part of another group, refers to one or more alkoxyl (—OR) moieties, wherein R is selected from the alkyl, alkenyl, alkynyl, aryl, aralkyl, and heteroaryl groups described above.

As used herein, “thiol,” by itself or as part of another group, refers to an (—SH) moiety.

As used herein, “alkylthio,” refers to an (—SR) moieties, wherein R is selected from the alkyl, alkenyl, alkynyl, aryl, aralkyl, and heteroaryl groups described above.

As used herein, “silyl,” by itself or as part of another group, refers to an (—SiH₃) moiety.

As used herein, “alkylsilyl,” by itself or as part of another group, refers to an (—Si(R)ₓH_{y}) moiety, wherein 1≦x≦3 and y=3-x, and wherein R is independently selected from the alkyl alkenyl, alkynyl, aryl, aralkyl, and heteroaryl groups described above.

As used herein, “alkylsilenyl,” by itself or as part of another group, refers to a (—Si(═R)H) moiety, wherein R is selected from the alkyl, alkenyl, alkynyl, aryl, aralkyl, and heteroaryl groups described above.

As used herein, “siloxyl,” by itself or as part of another group, refers to a (—Si(OR)ₓR¹_{y}) moiety, wherein 1≦x≦3 and y=3-x, wherein R and R¹ are independently selected from hydrogen and the alkyl, alkenyl, alkynyl aryl, aralkyl, and heteroaryl groups described above.

As used herein, “primary amino,” by itself or as part of another group, refers to an (—NH₂) moiety.

As used herein, “secondary amino,” by itself or as part of another group, refers to an (—NRH) moiety, wherein R is selected from the alkyl, alkenyl, alkynyl, aryl, aralkyl, and heteroaryl groups described above.

As used herein, “tertiary amino,” by itself or as part of another group, refers to an (—NRR¹) moiety, wherein R and R¹ are independently selected from the alkyl, alkenyl, alkynyl, aryl, aralkyl, and heteroaryl groups described above.

As used herein. “carbonyl,” by itself or as part of another group, refers to a (C═O) moiety.

As used herein, “alkylcarbonyl,” by itself or as part of another group, refers to a (—C(═O)R) moiety, wherein R is independently selected from hydrogen and the alkyl, alkenyl, alkynyl, aryl, aralkyl, and heteroaryl groups described above.

As used herein, “aminocarbonyl,” by itself or as part of another group, refers to a (—C(═O)NRR¹) moiety, wherein R and R¹ are independently selected from hydrogen and the alkyl, alkenyl, alkynyl, aryl, aralkyl, and heteroaryl groups described above.

As used herein, “carbonylamino,” by itself or as part of another group, refers to a (—N(R)C(═O)R¹) moiety, wherein R and R¹ are independently selected from hydrogen and the alkyl, alkenyl, alkynyl, aryl, aralkyl, and heteroaryl groups described above.

As used herein, “carboxy,” by itself or as part of another group, refers to a (—COOR) moiety, wherein R is independently selected from hydrogen and the alkyl, alkenyl, alkynyl, aryl, aralkyl and heteroaryl groups described above.

The pattern formed by the first material has a first surface characteristic. As used herein, a “surface characteristic” refers to the chemical functionality of the surface of a pattern formed by the first material. Most generally, the chemical functionality of the pattern can be hydrophilic or hydrophobic. As used herein, hydrophilic surfaces are those on which water forms a contact angle, Θ, wherein Θ≦90°. As used herein, hydrophobic surfaces are those on which water forms a contact angle, Θ, wherein Θ>90°. Hydrophilic surfaces can further comprise: hydrogen-bond donating surfaces, hydrogen-bond receiving surfaces, chemically reactive surfaces, and combinations thereof. As used herein, a hydrogen-bond donating surface has an exposed functional group containing an —NHₓ or —OH group, wherein x is 1 or 2. As used herein, a hydrogen-bond receiving surface has a functional group containing an exposed N, O, or F atom having a lone pair of electrons. As used herein, a chemically reactive surface has an exposed functional group other than an alkyl, fluoroalkyl or perfluoroalkyl group.

Functional groups suitable for imparting hydrophobicity to a surface pattern include, but are not limited to, hydrocarbon, halo, perhalo, and combinations thereof.

As used herein, “halo,” by itself or as part of another group, refers to any of the above alkyl, alkenyl, alkynyl, aryl, aralkyl, and heteroaryl groups wherein one or more hydrogens thereof are substituted by one or more fluorine, chlorine, bromine, or iodine atoms.

As used herein. “perhalo,” by itself or as part of another group, refers to any of the above alkyl, alkenyl, alkynyl, aryl, aralkyl, and heteroaryl groups wherein all of the hydrogens thereof are substituted by fluorine, chlorine, bromine, or iodine atoms.

Functional groups suitable for imparting hydrophilicity to a surface pattern include: but are not limited to, hydroxyl, alkoxyl, thiol, thioalkyl, silyl, alkylsilyl, alkylsilenyl, siloxyl, primary amino, secondary amino, tertiary amino, carbonyl, alkylcarbonyl, aminocarbonyl, carbonylamino, carboxy, alkylenedioxy, and combinations thereof. Not being bound by any particular theory, alkylsilyl, alkylsilenyl, siloxyl, primary amino, secondary amino, tertiary amino, alkylcarbonyl, aminocarbonyl, carbonylamino, and carboxy functional groups can also impart hydrophobicity to a surface depending on the presence and length of an —R group attached to the functional group. Generally, increasing the length of an alkyl, alkenyl, or alkynyl chain will increase the hydrophobicity of the surface.

As used herein, “alkylenedioxy,” by itself or as part of another group, refers to a ring and is especially C₁₋₄ alkylenedioxy. Alkylenedioxy groups can optionally be substituted with halogen (especially fluorine). Typical examples include methylenedioxy (—OCH₂O—) or difluoromethylenedioxy (—OCF₂O—).

In some embodiments, a process of the present invention further comprises depositing onto the substrate a second pattern comprising a second material having a second surface characteristic, wherein the second surface characteristic is different from the first surface characteristic of the first material, and wherein the second pattern substantially covers a second area of the substrate. For example, a first pattern comprising a first material having a hydrophobic surface characteristic can be deposited onto a first area of an unmasked substrate, and a second pattern can be deposited on a second area of the unmasked substrate, wherein the second pattern comprises a material having a hydrophilic surface characteristic (e.g., a hydrogen-bond donating characteristic).

An optional second pattern can be deposited by any of the processes suitable for depositing the first pattern onto the unmasked substrate, as well as deposition processes such as spin-coating, dip-coating, spray-coating, and the like that can uniformly coat the substrate.

The processes of the present invention comprise disposing onto a substrate a composition having a functional group suitable for associating with the surface of a pattern, wherein the composition deposits preferentially on the pattern to form an amplified pattern, and wherein an area of the unmasked substrate not covered by the pattern is substantially free from the composition.

Compositions suitable for use with the present invention include, but are not limited to: oils, inks, gels, pastes, foams, colloids, adhesives, and the like comprising at least one of the molecular species, oligomers, dendrimers, polymers, and combinations thereof described herein. Disposition of the composition upon the pattern comprising the first material results in the formation of an “amplified pattern.” Not being bound by any particular theory, the amplified pattern is more robust to degradation by mechanical stress, mechanical abrasion, exposure to reactant chemical species, exposure to thermal energy, and combinations thereof because of its increased thickness and due to stability imparted to the amplified pattern by the interaction of functional groups within the composition with each other (i.e., in situ interactions) and between the composition and the pattern comprising the first material (i.e., ex situ interactions).

In some embodiments, the etch resistance of the amplified pattern (i.e., resistance to wet and/or dry etchants) is increased by about 300%, about 400%, or about 500% compared to the pattern comprising the first material. Etch resistance can be measured, for example, by the change in pinhole area, pinhole density, the change in etch rate, and the deviation in surface feature dimensions from target specifications.

A composition can be disposed to a patterned substrate by methods known in the art such as, but not limited to, screen printing, ink jet printing, syringe deposition, spraying, spin coating, dip-coating, stamping, brushing, and combinations thereof. In some embodiments, a composition is poured onto a patterned substrate, and then a rigid member (e.g., a blade, an edge of a rigid sheet, a wire, and the like) is moved transversely across a substrate to ensure that the composition evenly coats the surface. A rigid member can also remove excess composition from a substrate. Spin coating a composition can be achieved by applying a composition to a substrate while rotating the substrate at about 100 revolutions per minute (rpm) to about 5,000 rpm, or about 1,000 rpm to about 3,000 rpm, while pouring or spraying the composition onto the rotating surface.

In some embodiments, a composition comprises compound having a functional group complementary to (i.e., capable of associating with) a pattern on an unmasked substrate comprising a first material. In some embodiments, a composition comprises a compound having a functional group capable of associating with a surface of a pattern and not associating with a substrate (i.e., a functional group that is repelled by or does not have an affinity for a substrate). For example, in some embodiments, an unmasked hydrophilic substrate is patterned with a first material to form a pattern thereon having a hydrophobic surface. A hydrophobic composition is then disposed onto the substrate and deposits preferentially onto the hydrophobic pattern, while the unpatterned areas of the hydrophilic substrate remain substantially free, from the hydrophobic composition. Not being bound by any particular theory, this can arise from the hydrophobic composition lacking a functional group suitable for associating with the hydrophilic substrate.

Similarly, in some embodiments, an unmasked hydrophobic substrate is patterned with a first material to form a pattern thereon having a hydrophilic surface. A hydrophilic composition is then disposed onto the substrate and deposits preferentially onto the hydrophilic pattern, while the unpatterned areas of the hydrophobic substrate remain substantially free from the hydrophilic composition.

While compositions comprising compounds that include C—F and/or Si—F bonds can be particularly hydrophobic, and are therefore particularly suitable for a preferential disposition processes as described in e.g., U.S. Pat. No. 7,041,232. However, compounds comprising C—F bonds, and in particular perfluorocarbons, can have extraordinarily long environmental lifetimes. Therefore, a process capable of patterning a substrate without utilizing a compound comprising C—F and/or Si—F bonds can be desirable for minimizing environmental remediation and/or manufacturing costs. In some embodiments, the present invention is directed to a process in which the disposing comprises a composition that includes a compound lacking a C—F bond or a Si—F bond (e.g., a hydrocarbon). Thus, certain aspects of the present invention minimize the use of potential environmental contaminants while simultaneously providing greater efficiency and a the ability to pattern large-surface area substrates.

In some embodiments, the present invention is directed to a process in which the providing comprises a laminate substrate that includes a metal layer (e.g., Au, Cu, Ag, Pd, Pt, and the like) over a plastic or glass underlayer; the depositing comprises microcontact printing a first material that includes hexadecane thiol onto the metal layer; the disposing comprises a composition that includes hexadecane: and the reacting comprises etching wet etching or dry etching) the metal layer.

In some embodiments, the present invention is directed to a process in which the providing comprises a laminate substrate that includes a semiconductor layer (e.g., ZnO, ITO, CIGS, and the like) over a plastic or glass underlayer, the depositing comprises microcontact printing a first material that includes an alkyl-alkoxysiloxane onto the semiconductor layer; the disposing comprises a composition that includes hexadecane; and the reacting comprises etching (e.g., wet etching or dry etching) the semiconductor layer.

In some embodiments, an unmasked hydrophobic substrate is patterned with a first material to form a pattern thereon having a hydrophilic surface containing a hydrogen-bond accepting functional group. A hydrophilic composition containing a hydrogen-bond donating functional group is then disposed onto the substrate and deposits preferentially onto the hydrophilic pattern, while the unpatterned areas of the hydrophobic substrate remain substantially free from the hydrophilic composition.

Similarly, in some embodiments an unmasked hydrophobe substrate is patterned with a first material to form a pattern thereon having a hydrophilic surface containing a hydrogen-bond donating functional group. A hydrophilic composition containing a hydrogen-bond accepting functional group is then disposed onto the substrate and deposits preferentially onto the hydrophilic pattern, while the unpatterned areas of the hydrophobic substrate remain substantially free from the hydrophilic composition.

In some embodiments, the disposing is performed in about 1 minute or less, about 45 seconds or less, about 30 seconds or less, about 20 seconds or less, about 15 seconds or less, or about 10 seconds or less. In some embodiments, the combination of the depositing and the disposing are performed in about 1 minute or less, about 45 seconds or less, about 30 seconds or less, or about 20 seconds or less. In some embodiments, the combination of the depositing and the disposing are performed in about 1 minute or less, about 45 seconds or less, about 30 seconds or less, or about 20 seconds or less on a substrate having a surface area of about 400 cm² or greater, about 500 cm² or greater, about 750 cm² or greater, about 1,000 cm² or greater, or about 1,500 cm² or greater.

In some embodiments, the amplified pattern is solidified. Methods suitable for solidifying the amplified, pattern include, but are not limited to, applying thermal energy to the amplified pattern, removing solvent from the amplified pattern, exposing the amplified pattern to UV light, catalyzing cross-linking the amplified pattern, and combinations thereof.

In some embodiments, a property of the first material, second material, and/or composition can be selected to optimize the patterning process of the present invention. For example, properties such as, but not limited to, viscosity, particle size, density, and combinations thereof can be selected to optimize the patterning process.

In some embodiments, a composition can be formulated to control its viscosity. Parameters that can control viscosity include, but are not limited to, solvent: composition, solvent concentration, the addition of a thickener, thickener concentration, particles size, molecular weight, the degree of cross-linking, the free volume (i.e., porosity) of a component, the swellability of a component, ionic interactions between components (e.g., solvent-thickener interactions), and combinations thereof.

In some embodiments, a first material, second material, and/or composition suitable for use with the present invention has a viscosity of about 1 centiPoise (cP) to about 10,000 cP. In some embodiments, a first material, second material, and/or composition for use with the present invention has a tunable viscosity, and/or a viscosity that can be controlled by one or more external conditions. In some embodiments, a paste for use with the present invention has a viscosity of about 1 cP to about 10,000 cP, about 1 cP to about 8,000 cP, about 1 cP to about 5,000 cP, about 1 cP to about 2,000 cP, about 1 cP to about 1,000 cP, about 1 cP to about 500 cP, about 1 cP to about 100 cP, about 1 cP to about 80 cP, about 1 cP to about 50 cP, about 1 cP to about 20 cP, about 1 cP to about 10 cP, about 10 cP to about 10,000 cP, about 10 cP to about 8,000 cP, about 10 cP to about 5,000 cP, about 10 cP to about 2,000 cP, about 10 cP to about 1,000 cP, about 10 cP to about 500 cP, about 10 cP to about 100 cP, about 10 cP to about 80 cP, about 10 cP to about 50 cP, about 10 cP to about 20 cP, about 100 cP to about 10,000 cP, about 100 cP to about 8,000 cP, about 100 cP to about 5,000 cP, about 100 cP to about 2,000 cP, about 100 cP to about 1,000 cP, about 100 cP to about 500 cP, 500 cP to about 10,000 cP, about 500 cP to about 8,000 cP, about 500 cP to about 5,000 cP, about 500 cP to about 2,000 cP, about 500 cP to about 1,000 cP, about 1,000 cP to about 10,000 cP, about 1,000 cP to about 8,000 cP, about 1,000 cP to about 5,000 cP, about 1,000 cP to about 2,000 cP, about 2,000 cP to about 10,000 cP, about 2,000 cP to about 8,000 cP, of about 5,000 cP to about 10,000 cP.

In some embodiments, the viscosity of a composition is modified during one or more of depositing (i.e., applying and/or disposing), reacting, and combinations thereof. For example, the viscosity can be decreased while applying the composition to the substrate to ensure that the substrate is evenly coated. After coating, the viscosity of the composition can be increased to ensure that the lateral dimensions of the amplified pattern are transferred to the lateral dimensions of a surface feature formed on the substrate.

Not being bound by any particular theory, the viscosity can be controlled by an external stimulus such as temperature, pressure, pH, the presence or absence of a reactive species, electrical current, a magnetic field, and combinations thereof. For example, increasing the temperature will typically decrease the viscosity of a composition; and increasing the pressure applied paste will typically increase the viscosity. The pH can either increase or decrease the viscosity of a composition depending on the properties of one or more components in the composition, depending on the overall solubility of the component mixture as a function of pH. For example, an aqueous composition containing a weakly acidic polymer will typically have a decreased viscosity below the pK, of the polymer because the solubility of the polymer will increase below its pK. However, if protonation of the polymer leads to an ionic interaction between the polymer and another component in the composition, then the viscosity can increase. Careful selection of components permits the viscosity of a composition to be controlled over a wide range of pH values.

In some embodiments, a first material, second material, and/or composition suitable for use with the present invention is “heterogeneous,” which refers to having more than one excipient or component. In some embodiments, a first material, second material, and/or composition suitable for use with the present invention comprises at least one of a solvent, a thickening agent, and combinations thereof. In some embodiments, the concentration or type of solvent and/or thickening agent can be selected to adjust the viscosity of the first material, second material, and/or composition.

Thickening agents suitable for use with a paste of the present invention include, but are not limited to, metal salts of carboxyalkylcellulose derivatives (e.g., sodium carboxymethylcellulose), alkylcellulose derivatives (e.g., methylcellulose, ethylcellulose, and the like), partially oxidized alkylcellulose derivatives (e.g., hydroxyethylcellulose, hydroxypropylcellulose, hydroxypropylmethylcellulose, and the like), starches, polyacrylamide gels, homopolymers of poly-N-vinylpyrrolidone, poly(alkylethers) polyethylene oxide, polypropylene oxide, and the like), agar, agarose, xanthan gums, gelatin, dendrimers, colloidal silicon dioxide, and combinations thereof. In some embodiments, a thickener is present in first material, second material, and/or composition in a concentration of about 0.5% to about 25%, about 1% to about 20%, or about 5% to about 15% by weight of the first material, second material, and/or composition.

In some embodiments, as the lateral dimensions of the desired surface features decrease it is necessary to reduce the particle size or physical length of components in the first material, second material, or composition. For example, for surface features having a lateral dimension of about 100 nm or less, it can be necessary to reduce or eliminate polymeric components from a first material, second material, and/or composition.

Solvents suitable for use with a first material, second material, or composition of the present invention include, but are not limited to, water, C₁-C₈ alcohols (e.g., methanol, ethanol, propanol, butanol, and the like). C₆-C₁₂ straight chain, branched and cyclic hydrocarbons (e.g., hexane, cyclohexane, heptane, octane, cyclooctane, and the like), C₆-C₁₄ aryl and aralkyl hydrocarbons (e.g., benzene, toluene, and the like), C₃-C₁₀ alkyl ketones (e.g., acetone, methylethylketone, and the like). C₃-C₁₀ esters (e.g., ethyl acetate, and the like). C₄-C₁₀ alkyl ethers (e.g., diethylether, methylbutylether, and the like), amides (e.g., dimethylformamide, dimethylacetamide, N-methylpyrrolidone, and the like), and combinations thereof. In some embodiments, a solvent is present in a first material, second material, or composition in a concentration of about 10% to about 90%, or about 15% to about 85% by weight of the first material, second material, or composition.

### Surface Features

The process of the present invention comprises: reacting the area of the substrate adjacent to an amplified pattern to form a surface feature thereon, wherein the area of the substrate having an amplified pattern thereon is substantially not reacted. As used herein, a “surface feature” refers to an area of a surface that is contiguous with, and can be distinguished from, the areas of the substrate surrounding the feature. For example, a surface feature can be distinguished from the areas of the substrate surrounding the feature based upon the topography of the surface feature, composition of the surface feature, or another property of the surface feature that differs from the surrounding areas of the substrate. In some embodiments, a surface feature is formed on the area or areas of the substrate substantially not covered by the pattern comprising a first material.

In some embodiments, the present invention is directed to a patterned substrate comprising:
(a) a first area of the substrate having a pattern thereon, the pattern comprising:
   (i) a first layer contacting the substrate, wherein the first layer comprises a material having a first surface characteristic; and
   (ii) a second layer contacting the first layer, wherein the second layer comprises a composition having a second surface characteristic, wherein the second surface characteristic has an affinity to the first surface characteristic of the first layer; and
(b) a second area of the substrate having a feature thereon, wherein the feature is not present on the first area of the substrate, and wherein the feature has a surface characteristic incompatible with the surface characteristics of the first and the second layers.

Surface features can be defined by their physical dimensions. All surface features have at least one lateral dimension. As used herein, a “lateral dimension” refers to a dimension of a surface feature that lies in the plane of a surface. One or more lateral dimensions of a surface feature define, or can be used to define, the area of a surface that a surface feature occupies. Typical lateral dimensions of Surface features include, but are not limited to: length, width, radius, diameter, and combinations thereof.

All surface features also have at least one dimension that can be described by a vector that lies out of the plane of the surface. As used herein, “elevation” refers to the largest vertical distance between the plane of a surface and the highest or lowest point on a surface feature. More generally, the elevation of an additive surface feature refers to its highest point relative to the plane of the surface, the elevation of a subtractive surface feature refers to its lowest point relative to the plane of the surface, and a conformal surface feature has an elevation of zero (i.e., is at the same height as the plane of the surface).

When the surrounding surface area is planar, a lateral dimension of a surface feature is the magnitude of a vector between two points located on opposite sides of a surface feature, wherein the two points are in the plane of the surface, and wherein the vector is parallel to the plane of the surface. In some embodiments, two points used to determine a lateral dimension of a symmetric surface also lie on a mirror plane of the symmetric feature. In some embodiments, a lateral dimension of an asymmetric surface can be determined by aligning the vector orthogonally to at least one edge of the surface feature.

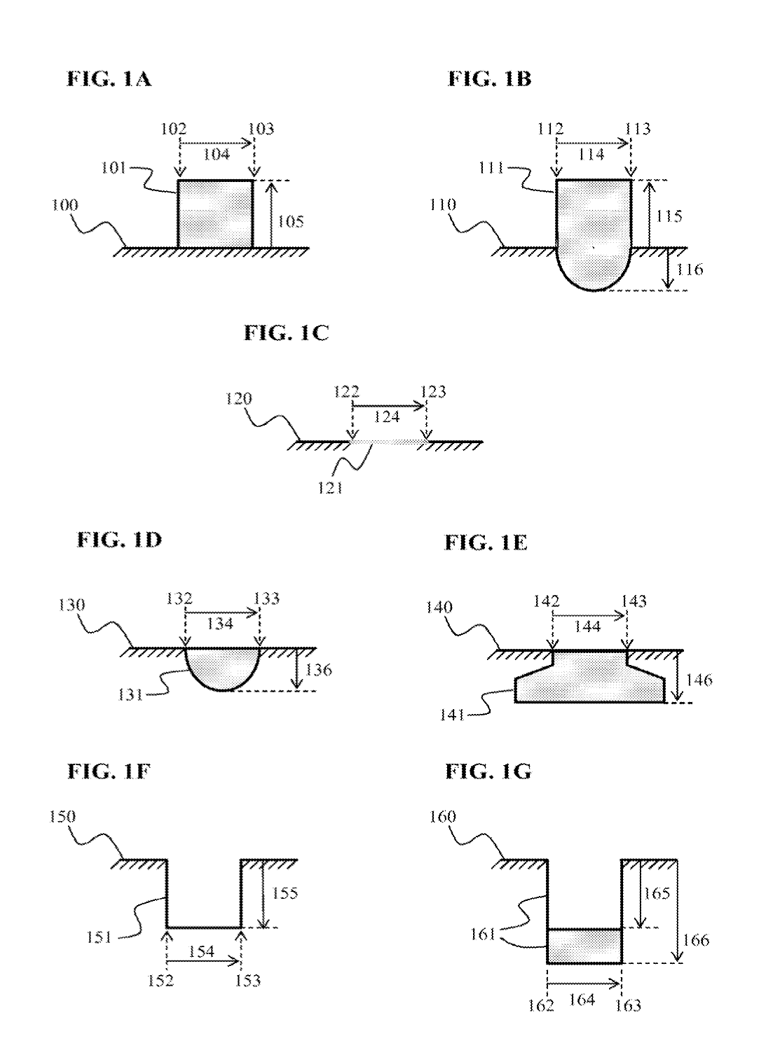

For example, in FIGS. 1A-1G points lying in the plane of the surface and on opposite sides of the surface features, 101, 111, 121, 131, 141, 151 and 161, are indicated by dashed arrows, 102 and 103; 112 and 113; 122 and 123; 132 and 133; 142 and 143; 152 and 153, and 162 and 163, respectively. The lateral dimension of these surface features is shown by the magnitude of the vectors 104, 114, 124, 134, 144, 154 and 164, respectively.

Surface features produced by the processes of the present invention can generally be classified into three groups: additive features, conformal features, and subtractive features, based upon the elevation of the surface feature relative to the plane of the substrate.

Surface features produced by the processes of the present invention can be further classified into two-subgroups: penetrating and non-penetrating, based upon whether or not the base of a surface feature penetrates below the plane of the substrate. As used herein, the “penetration distance” refers to the distance between the lowest point of a surface feature and the height of the surface adjacent to the surface feature. More generally, the penetration distance of a surface feature refers to its lowest point relative to the plane of the surface. Thus, a feature is said to be “penetrating” when its lowest point is located below the plane of the surface on which the feature is located, and a feature is said to be “non-penetrating” when the lowest point of the feature is located within or above the plane of the surface. A non-penetrating surface feature can be said to have a penetration distance of zero.

As used herein, an “additive feature” refers to a surface feature having an elevation that is above the plane of the substrate. Thus, the elevation of an additive feature is greater than the elevation of the surrounding surface area FIG. 1A shows a cross-sectional schematic representation of a substrate, 100, having an “additive non-penetrating” surface feature, 101. The surface feature, 101 has a lateral dimension, 104, an elevation, 105, and a penetration distance of zero. FIG. 1B shows a cross-sectional schematic representation of a substrate, 110, having an “additive penetrating” surface feature, 111. The surface feature, 111, has a lateral dimension, 114, an elevation, 115, and a penetration distance, 116.

As used herein, a “conformal feature” refers to a surface feature having an elevation that is even with the plane of a substrate. Thus, a con formal feature has substantially the same topography as the surrounding areas of the substrate. As used herein, a “conformal non-penetrating” surface feature refers to a surface feature that is purely on the surface of a substrate. For example, exposure of an unpatterned area of a substrate with, for example, an oxidant, reducing agent, or functionalizing agent, can result in the formation of a conformal non-penetrating surface feature. FIG. 1C shows a cross-sectional schematic representation of a substrate, 120, having a “conformal non-penetrating” surface feature, 121. The surface feature, 121, has a lateral dimension, 124, and has an elevation of zero and at penetration distance of zero. FIG. 1D shows a cross-sectional schematic representation of a substrate, 130, having a “conformal penetrating” surface feature, 131. The surface feature, 131, has a lateral dimension, 134, an elevation of zero, and penetration distance, 136. FIG. 1E shows a cross-sectional schematic representation of a substrate, 140, having a “conformal penetrating” surface feature, 141. The surface feature, 141, has a lateral dimension, 144, an elevation of zero, and penetration distance, 146.

As used herein, a “subtractive feature” refers to a surface feature having an elevation that is below the plane of the substrate. FIG. 1F shows a cross-sectional schematic representation of a substrate, 150, having a “subtractive non-penetrating” surface feature, 151. The surface feature, 151, has a lateral dimension, 154, an elevation, 155, and penetration distance of zero. FIG. 1G shows a cross-sectional schematic representation of a substrate, 160, having a “subtractive penetrating” surface feature, 161. The surface feature, 161, has a lateral dimension, 164, an elevation, 165, and a penetration distance, 166.

A surface is “curved” when the radius of curvature of a surface is non-zero over a distance on the surface of 100 μm or more, or over a distance on the surface of 1 mm or more. For a curved surface, is lateral dimension is defined, as the magnitude of a segment of the circumference of a circle connecting two points on opposite sides of the surface feature, wherein the circle has a radius equal to the radius of curvature of the surface. A lateral dimension of a curved surface having multiple or undulating curvature, or waviness, can be determined by summing the magnitude of segments from multiple circles.

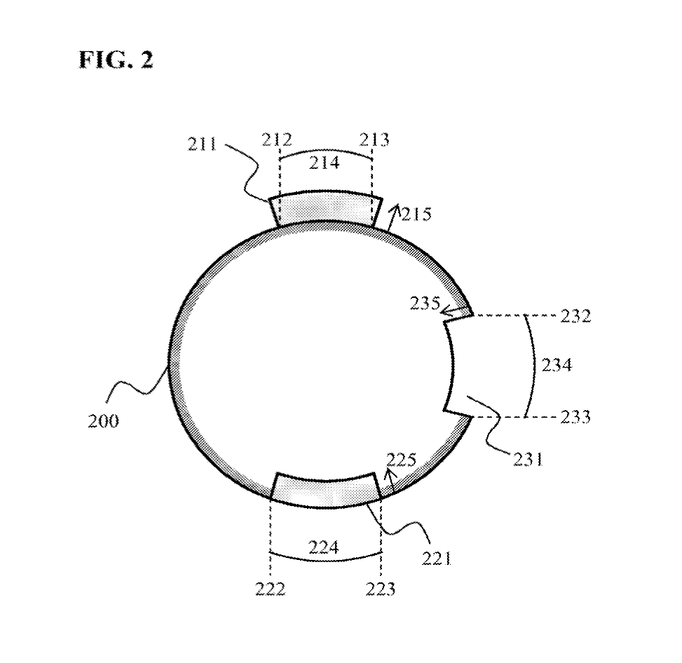

FIG. 2 displays a cross-sectional schematic of a curved surface, 200, that includes an additive non-penetrating surface feature, 211, a conformal penetrating surface feature, 221, and a subtractive, non-penetrating surface feature, 231. A lateral dimension of the additive non-penetrating surface feature, 211, is equivalent to the length of the line segment, 214, which can connect points 212 and 213. Similarly, a lateral dimension of the conformal penetrating surface feature, 221, is equivalent to the length of the line segment, 224, which connect points 222 and 223. And a lateral dimension of the subtractive, non-penetrating surface feature, 231, is equivalent to the length of the line segment, 234, which connect points 232 and 233. The additive non-penetrating surface feature, 211, has an elevation equal to the height of the vector, 215, and penetration distance of zero. The conformal penetrating surface feature, 221, has an elevation of zero and a penetration distance equal to the depth of the vector, 225. The subtractive non-penetrating surface feature, 231, has an elevation equal to the height of the vector, 235, and penetration distance of zero.

A surface feature produced by a method of the present invention has lateral and vertical dimensions that are typically defined in units of length, such as angstroms (Å), nanometers (nm), microns (μm), millimeters (mm), centimeters (cm), etc.

In some embodiments, a surface feature produced by a method of the present invention has at least one lateral dimension of about 100 μm or less, about 40 nm to about 100 μm, about 40 nm to about 80 μm, about 40 nm to about 50 μm, about 40 nm to about 20 μm, about 40 nm to about 10 μm, about 40 nm to about 5 μm, about 40 nm to about 1 μm, about 100 nm to about 100 μm, about 100 nm to about 80 μm, about 100 nm to about 50 μm, about 100 nm to about 20 μm, about 100 nm to about 10 μm, about 100 nm to about 5 μm, about 100 nm to about 1 μm, about 500 nm to about 100 μm, about 500 nm to about 80 μm, about 500 nm to about 50 μm, about 500 nm to about 20 μm, about 500 nm to about 10 μm, about 500 nm to about 5 μm, about 500 nm to about 1 μm, about 1 μm to about 100 μm, about 1 μm to about 80 μm, about 1 μm to about 50 μm, about 1 μm to about 20 μm, about 1 μm to about 10 μm, about 1 μm, to about 5 μm, or about 1 μm.

In some embodiments, a feature produced by a method of the present invention has an elevation or penetration distance of about 3 Å to about 100 μm, about 3 Å to about 50 μm, about 3 Å to about 10 μm, about 3 Å to about 1 μm, about 3 Å to about 500 nm, about 3 Å to about 100 nm, about 3 Å to about 50 nm, about 3 Å to about 10 nm, about 3 Å to about 1 nm, about 1 nm to about 100 μm, about 1 nm to about 50 μm, about 1 nm to about 10 μm, about 1 nm to about 1 μm, about 1 nm to about 500 nm, about 1 nm to about 100 nm, about 1 nm to about 50 μm, about 1 nm to about 10 nm, about 10 nm to about 100 nm, about 10 nm to about 50 μm, about 10 nm to about 10 μm, about 10 nm to about 1 μm, about 10 nm to about 500 nm, about 10 nm to about 100 nm, about 10 nm to about 50 nm, about 50 nm to about 100 μm, about 50 nm to about 50 μm, about 50 nm to about 10 μm, about 50 nm to about 1 μm, about 50 nm to about 500 nm, about 50 nm to about 100 nm, about 100 nm to about 100 μm, about 100 nm to about 50 μm, about 100 nm to about 10 μm, about 100 nm to about 1 μm, or about 100 nm to about 500 nm above or below the plane of a surface.

In some embodiments, a surface feature produced by a method of the present invention has an aspect ratio (i.e., a ratio of either one or both of the elevation and/or penetration distance to a lateral dimension) of about 100:1 to about 1:1,000,000, about 50:1 to about 1:100,000, about 40:1 to about 1:10,000, about 30:1 to about 1:1,000, about 20:1 to about 1:100, about 15:1 to about 1:50, about 10:1 to about 1:10, about 8:1 to about 1:8, about 5:1 to about 1:5, about 2:1 to about 1:2, or about 1:1,

In some embodiments, a surface feature produced by a process of the present invention comprises rounded edges (i.e., is substantially lacking corners having edges 90° from one another).

Surface features can be further differentiated based upon their composition and utility. For example, surface features produced by a method of the present invention include structural surface features, conductive surface features, semi-conductive surface features, insulating surface features, and masking surface features.

As used herein, a “structural feature” refers to surface feature having a composition similar or identical to the composition of the substrate on which the surface feature is produced.

As used herein, a “conductive feature” refers to a surface feature having a composition that is electrically conductive, or electrically semi-conductive. Electrically semi-conductive features include surface features whose electrical conductivity can be modified based upon an external stimulus such as, but not limited to, an electrical field, a magnetic field, a temperature change, a pressure change, exposure to radiation, and combinations thereof.

As used herein, an “insulating feature” refers to a surface feature having a composition that is electrically insulating.

As used herein, a “masking feature” refers to a surface feature that has composition that is inert to reaction with a reagent that is reactive towards the areas of the substrate adjacent to and surrounding the surface feature. Thus, a masking feature can be used to protect a substrate or a selected area of a substrate during subsequent process steps, such as, but not limited to, etching, deposition, implantation, and surface treatment steps, in sonic embodiments, a masking feature is removed during or after subsequent process steps.

A lateral and/or vertical dimension of an additive or subtractive surface feature can be determined using an analytical method that can measure surface topography such as, for example, scanning mode atomic force microscopy (AFM) or profilometry. Conformal surface features cannot typically be detected by profilometry methods. However, if the surface of a conformal surface feature is terminated with a functional group whose polarity differs from that of the surrounding surface areas, a lateral dimension of the surface feature can be determined using, for example, tapping mode AFM, functionalized AFM, or scanning probe microscopy.

Surface features can also be identified based upon a property such as, but not limited to, conductivity, resistivity, density, permeability, porosity, hardness, and combinations thereof using, for example, scanning probe microscopy.

In some embodiments, a surface feature can be differentiated from the surrounding surface area using, for example, scanning electron microscopy or transmission electron microscopy.

In some embodiments, a surface feature has a different composition or morphology compared to the surrounding surface area. Thus, surface analytical methods can be employed to determine both the composition of the surface feature, as well as the lateral dimension of the surface feature. Analytical methods suitable for determining the composition and lateral and vertical dimensions of a surface feature include, but are not limited to, Auger electron spectroscopy, energy dispersive x-ray spectroscopy, micro-Fourier transform infrared spectroscopy, particle induced x-ray emission, Raman spectroscopy, x-ray diffraction, x-ray fluorescence, laser ablation inductively coupled plasma mass spectrometry, Rutherford backscattering spectrometry/Hydrogen forward scattering, secondary ion mass spectrometry, time-of-flight secondary ion mass spectrometry, x-ray photoelectron spectroscopy, and combinations thereof.

The processes of the present invention produce surface features by reacting a component or reagent with an area of a substrate substantially not covered by an amplified pattern. As used herein, “reacting” refers to initiating a chemical reaction comprising at least one of: reacting one or more components with each other, reacting one or more components with a surface of a substrate, reacting one or more components with a sub-surface region of a substrate, and combinations thereof.

In some embodiments, the reacting comprises contacting a reactive component with the surface of a substrate (i.e., a reaction is initiated upon contact between a reactive component and a substrate).

Surface features can be farmed by reactions including, but not limited to, etching, electroplating, cleaning, chemically oxidizing, chemically reducing, exposing to ultraviolet light, exposing to thermal energy, exposing to a plasma, and combinations thereof. In some embodiments, surface features are formed by at least one of: etching, electroplating, cleaning, chemically oxidizing, chemically reducing, exposing to ultraviolet light, exposing to thermal energy, and exposing to a plasma, the area of the substrate not covered by the amplified pattern.

Etching processes suitable for forming surface features of the present invention include, but are not limited to, wet etching, dry etching, reactive ion etching, and combinations thereof. As used herein, an “etchant” refers to a component that can react with a substrate to remove a portion of the substrate. Thus, an etchant is used to form a subtractive feature, and in reacting with a substrate, forms at least one of a volatile and/or soluble material that can diffuse away from the substrate, or a residue, particulate, or fragment that can be removed from the substrate by, for example, a rinsing or cleaning process.

The composition and/or morphology of a substrate that can react with an etchant is not particularly limited. Subtractive features formed by reacting an etchant with a substrate are also not particularly limited so long as the material that reacts with the etchant can be removed from the resulting subtractive surface feature. Not being bound by any particular theory, an etchant can remove material from at surface by reacting with the surface to form a volatile product, a residue, a particulate, or a fragment that can, for example, be removed from the surface by a rinsing or cleaning process. For example, in sonic embodiments an etchant can react with a metal or metal oxide surface to form a volatile fluorinated metal species. In some embodiments, an etchant can react with as surface to form an ionic species that is water soluble. Additional processes suitable for removing a residue or particulate formed by reaction of an etchant with a surface are disclosed in U.S. Pat. No 5,894,853, which is incorporated herein by reference in its entirety.

Etchants suitable for use with the present invention include, but are not limited to, an acidic etchant, a basic etchant, a fluoride-based etchant, and combinations thereof. Acidic etch ants suitable for use with the present invention include, but are not limited to, sulfuric acid, trifluoromethanesulfonic acid, fluorosulfonic acid, trifluoroacetic acid, hydrofluoric acid, hydrochloric acid, carborane, acid, and combinations thereof.

Basic etchants suitable for use with the present invention include, but are not limited to, sodium hydroxide, potassium hydroxide, ammonium hydroxide, tetraalkylammonium hydroxide ammonia, ethanolamine, ethylenediamine, and combinations thereof.

Fluoride-based etchants suitable for use with the present invention include, but are not limited to, ammonium fluoride, lithium fluoride, sodium fluoride, potassium fluoride, rubidium fluoride, cesium fluoride, francium fluoride, antimony fluoride, calcium fluoride, ammonium tetrafluoroborate, potassium tetra and combinations thereof.

Additional reactant compositions that contain an etchant suitable for use with the present invention are disclosed in U.S. Pat. Nos. 5,688,366 and 6,388,187; and U.S. Patent Appl. Pub. Nos. 2003/0160026; 2004/0063326; 2004/0110393; and 2005/0247674, which are herein incorporated by reference in their entirety.

In some embodiments, a surface feature can be formed on a substrate by reacting a diffusive component with the substrate. As used herein, a “diffusive component” refers to a compound or species that has a chemical interaction with a surface. In some embodiments, a diffusive reactant penetrates into the body of material beneath its surface, and can transform, bind, or promote association with exposed functional groups on the surface of a substrate. Diffusive components can include, but are not limited to, ions, free radicals, metals, acids, bases, metal salts, organic reagents, and combinations thereof.

In some embodiments, a surface feature can be formed on as substrate by reacting a conductive component with the substrate. As used herein, a “conductive component” refers to a compound or species that upon reacting forms a surface feature that can transfer or move electrical charge. Conductive components suitable for use with the present invention include, but are not limited to, a metal, a nanoparticle, a polymer, a cream solder, a resin, and combinations thereof. In some embodiments, a conductive component can react with the surface through a process of electroplating.

Metals suitable for use with the present invention include, but are not limited to, a transition metal, aluminum, silicon, phosphorous, gallium, germanium, indium, tin, antimony, lead, bismuth, alloys thereof, and combinations thereof. In some embodiments, a conductive component comprises a nanoparticle (i.e., a particle having a diameter of 100 nm or less, or about 0.5 nm to about 100 nm). Nanoparticles suitable for use with the present invention can be homogeneous, multilayered, functionalized, and combinations thereof.

In some embodiments, a conductive component includes a conductive and/or semi-conductive polymer. Conductive and/or semi-conductive polymers suitable for use with the present invention include, but are not limited to, a polyaniline, a poly(3,4-ethylenedioxythiophene)-poly(styrenesulfonate), a polypyrrole, an arylene vinylene polymer, a polyphenylenevinylene, a polyacetylene, a polythiophene, a polyimidazole, and combinations thereof.

In some embodiments, a surface feature can be formed on a substrate by reaction with an insulating component. As used herein, an “insulating, component” refers to a compound or species that upon reacting forms a surface feature resistant to the movement or transfer of electrical charge. In some embodiments, an insulating component has a dielectric constant of about 1.5 to about 8 about 1.7 to about 5, about 1.8 to about 4. about 1.9 to about 3, about 2 to about 2.7, about 2.1 to about 2.5, about 8 to about 90, about 15 to about 85, about 20 to about 80, about 25 to about 75, or about 30 to about 70. Insulating components suitable for use with the present invention include, but are not limited to, a polymer, a metal oxide, a metal carbide, a metal nitride, monomeric precursors thereof, particles thereof and combinations thereof. Suitable polymers for use as insulating components include, but are not limited to, a polysiloxane, polysilsesquioxane, a polyethylene, a polypropylene, a polyimide, an poly(acrylate), an poly(alkylacryalate), and the like, and combinations thereof.

In some embodiments, a surface feature can be formed on a substrate by reacting a masking component: with the substrate. As used herein, a “masking component” refers to a compound or species that upon reacting forms a surface feature resistant to a species capable of reacting with the surrounding surface. Masking components suitable for use with the present invert don include materials commonly employed in traditional photolithography methods as “resists” (e.g., photoresists). Masking components suitable for use with the present invention, include, but are not limited to, cross-linked aromatic and aliphatic polymers, non-conjugated aromatic polymers and copolymers, polyethers, polyesters, copolymers of C₁-C₈ alkyl methacrylates and acrylic acid, copolymers of paralyne, and combinations thereof.

In some embodiments, a surface feature can be formed by reacting a combination of a conductive component and a reactive component with the substrate. For example, a reactive component can promote at least one of: penetration of a conductive component into a substrate, reaction between a conductive component and the substrate, adhesion between a conductive feature and a substrate, promoting electrical contact between a conductive feature and a substrate, and combinations thereof. Surface features formed by reacting this method include conductive surface features selected from: additive non-penetrating, additive penetrating, subtractive penetrating, and conformal penetrating surface features.

In some embodiments, a surface feature can be formed on a substrate by reacting a combination of an etchant and a conductive component, for example, that produces a subtractive surface feature having a conductive feature inset therein.

In some embodiments, a surface feature can be formed on a substrate by reacting a combination of an insulating component and a reactive component. For example, a reactive component can promote at least one of penetration of an insulating component into a substrate, reaction between the insulating component and a substrate, adhesion between an insulating feature and a substrate, promoting electrical contact between an insulating feature and a substrate, and combinations thereof. Surface features formed by this method include insulating features selected from: additive non-penetrating, additive penetrating, subtractive penetrating, and conformal penetrating surface features.

In some embodiments, a surface feature can be formed on a substrate by reacting a combination of an etchant and an insulating component, for example, that produces a subtractive surface feature having an insulating feature inset therein.

In some embodiments, a surface feature can be farmed on a substrate by reacting a combination of a conductive component and a masking component, for example, that can be used to produce electrically conductive masking features on a surface.

Not being bound by any particular theory, variables suitable for controlling the patterning process include, but are not limited to, the properties of the composition used to form the amplified pattern, the thickness of amplified pattern, temperature at which the process step(s) is performed, etc., in some embodiments, a process of the present invention can be optimized by designing printed patterns that display no sharp corners.

In some embodiments, the reacting comprises a chemical reaction between a component and a functional group on the substrate, or a chemical reaction between a component and a functional group below the surface of the substrate. Thus, methods of the present invention comprise reacting as component not only with a surface of a substrate, but also with a material below its surface, thereby forming inset or inlaid features in or on a substrate. Not being bound by any particular theory, a component can react with a substrate by reacting on the surface of the substrate, or penetrating and/or diffusing into the substrate.

Reaction between a component and substrate can modify one or more properties of areas of the substrate on which reacting occurs. For example, a reactive metal particle can penetrate the surface of a substrate, and upon reacting with the substrate, modify its conductivity. In some embodiments, a component can penetrate the surface of a substrate and react selectively to increase the porosity of the substrate in the areas (volumes) where reaction occurs. In some embodiments, a component can selectively react with a crystalline material to increase or decrease its volume, or change the interstitial spacing of a crystalline lattice.

In some embodiments, reacting comprises chemically reacting a functional group on the surface of a substrate with a component. In some embodiments, a reactive component can also react with only the surface of a material (i.e., no penetration and reaction with a material, occurs below its surface). In some embodiments, a patterning method wherein only the surface of a material is changed can be useful for subsequent self-aligned deposition reactions.

In some embodiments, reacting can comprise propagation of a reaction into the plane of the substrate, as well as reactions in the lateral plane of the substrate. For example, a reaction between an etchant and a substrate can comprise the etchant penetrating into the substrate in the vertical direction (i.e., orthogonally to the substrate), such that the lateral dimensions of the lowest point, of the surface feature are approximately equal to the dimensions of the feature at the plane of the substrate.

In particular, the present invention is directed to processes in which the reaction selectivity between a patterned area of a substrate and an unpatterned area of a substrate is improved, the process comprising:
(a) providing a substrate having a pattern formed thereon, wherein the pattern comprises a material having a first surface characteristic, wherein the pattern substantially covers a first area of the substrate;
(b) disposing onto the substrate a composition that deposits preferentially on the pattern via a covalent bonding interaction to form an amplified pattern, wherein an area of the substrate not covered by the pattern is substantially free from the composition, wherein the area of the substrate having the amplified pattern thereon has a reactivity with a reactant that is at least three times less than the reactivity with the reactant: of a the substrate having only the pattern thereon; and
(c) reacting the area of the substrate not covered by the pattern to form a surface feature thereon.

Thus, the amplified patterns of the present invention provide greater selectivity between an unpatterned area of a substrate and a patterned area of a substrate than is typically possible when a pattern has not been amplified. In some embodiments, an area of a substrate having an amplified pattern thereon exhibits a reactivity with a reactant that is at least three times, at least four times, at least five times, at least six times, at least eight times, or at least ten times less than the reactivity of an area of the substrate having a pattern onto which a compound has not been selectively disposed thereto (i.e., an area of a substrate having an unamplified pattern thereon).

In some embodiments, an area of a substrate having an amplified pattern thereon exhibits a reactivity with a reactant that is at least five times, at least six times, at least eight times, at least ten times, at least twelve times, at least fifteen times, or at least twenty times less than a reactivity of an area of the substrate that is substantially free from a pattern (e.g., a bare portion of a substrate).

In some embodiments, etching reactions also occur laterally in the plane of a substrate, such that the lateral dimensions at the bottom of a surface feature are more narrow than the lateral dimensions of the feature at the plane of the substrate. As used herein, “undercut” refers to situations when the lateral dimensions of a surface feature are greater than the area of the surface left exposed by the amplified pattern. Typically, undercut is caused by reaction of an etchant or reactive species with a substrate in a lateral dimension, and can lead to the formation of beveled edges on subtractive features, and result in deviation from target specifications for surface feature dimensions.

In some embodiments, reacting is initiated by light (i.e., reacting on the surface of a substrate begins upon exposure to radiation). For example, an etching component can be applied to a glass substrate that is transparent to UV light. Illumination of the etching component through the backside of the glass substrate initiates a reaction between the etchant and the substrate. Because the light illuminates only the surface etchant reacting vertically with the substrate, reaction along the sidewalls can be minimized, thereby minimizing lateral etching of the substrate. This technique is generally applicable to any reaction initiator that can be directed at the substrate.

Deviation from target specifications can also be minimized by the use of a substrate having an anisotropic composition or structure, such that reacting in the vertical direction is preferred compared to etching in a lateral dimension (i.e., reacting in the plane of the substrate). Sonic materials are naturally anisotropic, while anisotropy can also be introduced by, for example, pre-treating a surface with a chemical or radiation, and combinations thereof.

In some embodiments, reacting comprises removing or adding a solvent to a component. Not being bound by any particular theory, the removal of solvent from a component can result in the formation of solid surface features, or catalyze intermolecular and/or intramolecular cross-linking reactions between components. In some embodiments, solvent removal can be achieved by heating the substrate. Intermolecular and/or intramolecular cross-linking reactions can also be initiated by a catalyst, and can also occur between a component and the surface of the substrate.

In some embodiments, reacting comprises sintering a particulate metal component. As used herein, sintering refers to a process in which metal particles join to form a continuous structure within a surface feature without melting. Sintering be used to form both homogeneous and heterogeneous metal surface features.

In sonic embodiments, reacting comprises exposure to a reaction initiator. Reaction initiators suitable for use with the present invention include, but are not limited to thermal energy, radiation, acoustic waves, an oxidizing or reducing plasma, an electron beam, a stoichiometric chemical reagent, a catalytic chemical reagent, an oxidizing or reducing reactive gas, an acid or a base (e.g., a decrease or increase in pH), an increase or decrease in pressure, an alternating or direct electrical current, agitation, sonication, friction, and combinations thereof In some embodiments, reacting comprises exposure to multiple reaction initiators.

Radiation suitable for use as a reaction initiator can include, but is not limited to, electromagnetic radiation, such as microwave light, infrared light, visible light, ultraviolet light, x-rays, radiofrequency, and combinations thereof.

In some embodiments, a process of the present invention further comprises: removing the amplified pattern from the substrate. Processes suitable for removing the amplified pattern from the substrate include, but are not limited to, rinsing with an aqueous solvent, rinsing with an organic solvent, exposing to thermal energy, exposing to electromagnetic radiation, exposure to electrical current, and combinations thereof.

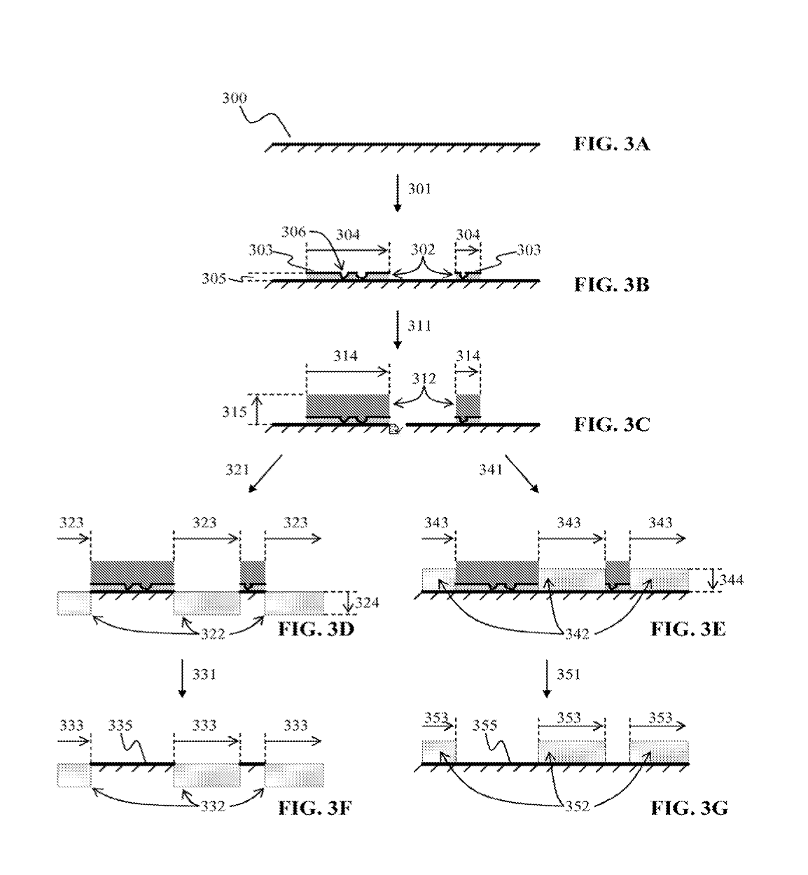

FIGS. 3A-3G display a schematic cross-sectional representation of an embodiment of the process of the present invention. Referring to FIGS. 3A and 3B, an unmasked substrate, 300, is patterned, 301, with a first material, 302, that forms a pattern on the substrate having a first surface characteristic, 303. The pattern has a lateral dimension, 304, and a vertical dimension (i.e., height), 305. The pattern can also comprise one or more defects, 306, that can include point defects, pinhole defects, grain boundary defects, and combinations thereof. After forming the pattern comprising a first material on the unmasked substrate a composition is disposed onto the substrate, 311. Referring to FIG. 3C, the composition, 312, preferentially wets the pattern by associating with the surface of the pattern, in some embodiments, the lateral dimensions, 314, of the amplified pattern are substantially similar to the lateral dimensions of the underlying pattern. The amplified pattern has at least one vertical dimension, 315. Referring to FIGS. 3D and 3E, an area of the substrate not covered by the amplified pattern can be reacted, 321 and 341, to form a surface feature. Penetrating, conformal surface features, 322, and additive surface features, 342, can be formed by the process of the present invention. The surface features formed by the process of the present invention have a lateral dimension, 323 and 343, respectively, defined by the lateral dimensions of the amplified pattern. The vertical dimension of the surface features, 324 and 344, respectively, can be controlled by the reactants used to produce the surface features. Referring to FIGS. 3F and 3G, in some embodiments, the amplified pattern can be removed, 331 and 351, respectively. The resulting architecture comprises a substrate, 335 and 355, respectively, having surface features, 332 and 352, thereon, wherein the lateral dimensions of the surface features, 333 and 353, are defined by the lateral dimensions of the amplified pattern.

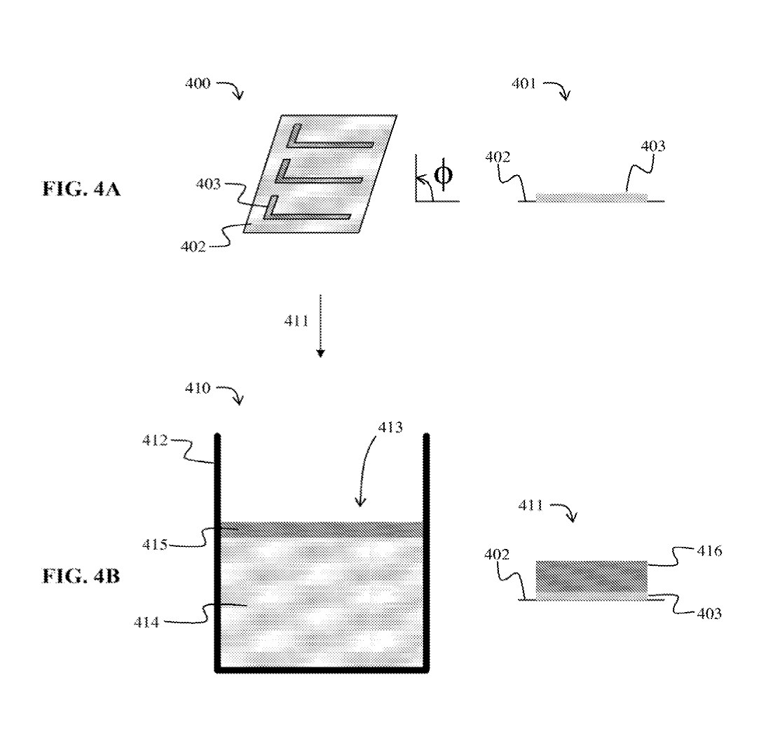

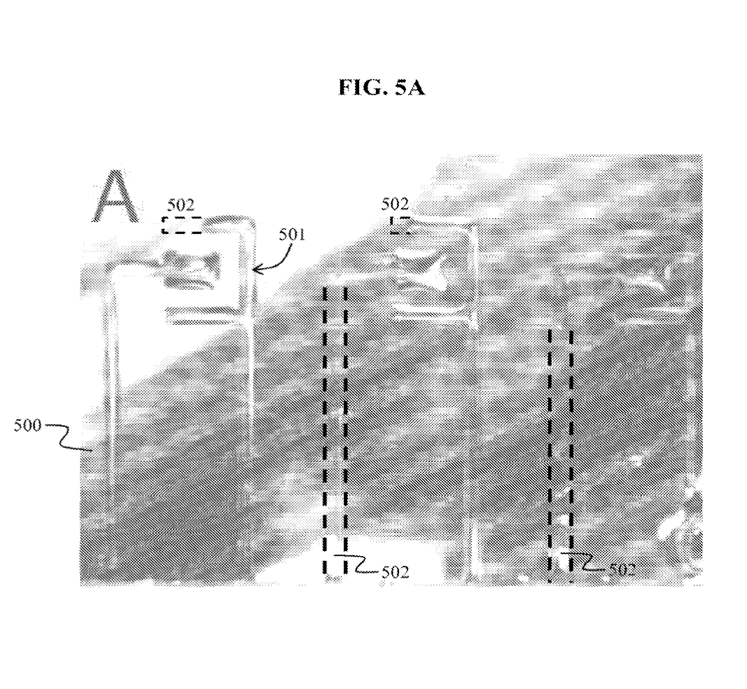

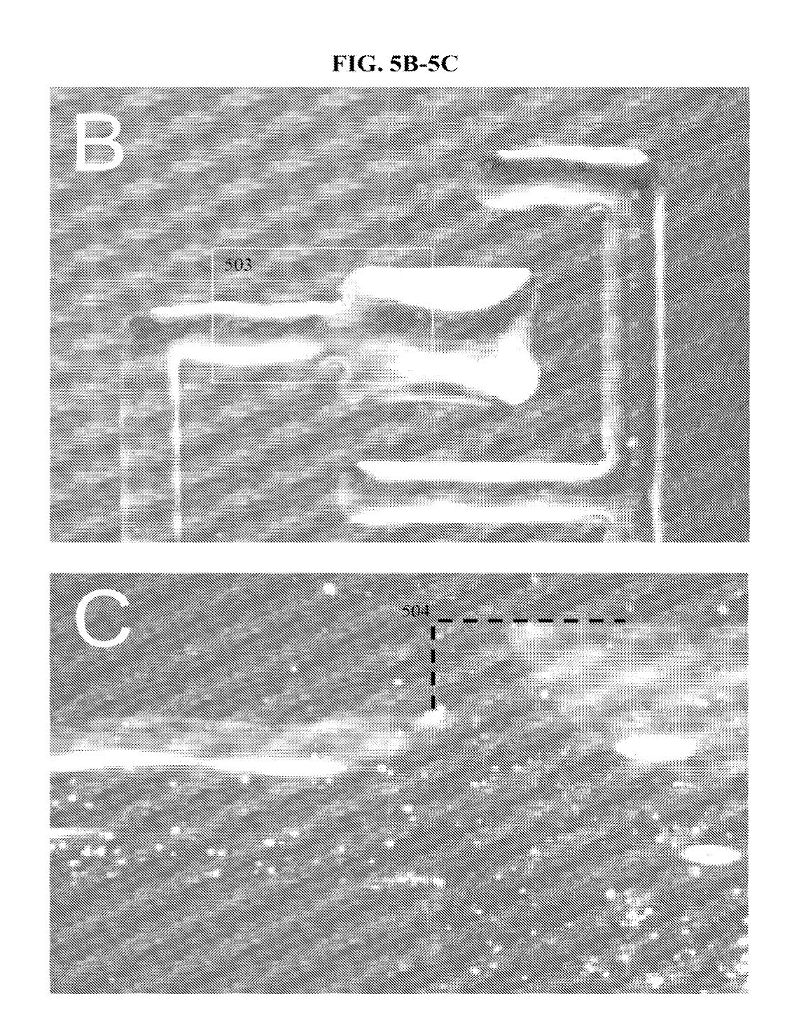

By way of example only and not limitation. FIGS. 4A and 4B display a schematic cross-sectional representation of an embodiment of the process of the present invention. Referring to FIG. 4A, a three-dimensional cross-sectional view, 409, is provided of an unmasked substrate, 402, having a pattern thereon, 403, comprising a first material, and having a first surface characteristic. (e.g., a hydrophobic surface characteristic such as that imparted by a SAM comprising hexadecane thiol on gold). An cross-sectional elevation of the same substrate-pattern configuration is also provided, 401. Referring to FIG. 4B, by way of example only and not limitation, a coating means is provided, 410, including a receptacle, 412, containing a liquid, 413, that includes an aqueous solution, 414, having above it a solution comprising a hydrophobic organic liquid (e.g., decane, dodecane, hexadecane), 415. The density of the hydrophobic organic liquid is less than that of the aqueous solution. The substrate, 402, is immersed into the liquid, 411. Upon passing through the solution, the hydrophobic organic liquid deposits preferentially on the pattern having a hydrophobic surface characteristic. An association between the hydrophobic organic liquid and the pattern causes the hydrophobic organic liquid to be deposited preferentially onto the pattern. A cross-sectional representation of the substrate after coating is depicted, 411, wherein the hydrophobic organic liquid deposits preferentially onto the pattern, 403, to form a composition thereon, 416. The unpatterned areas of the substrate, 402, are substantially not coated by the solution. In some embodiments, the angle of entry, φ, and orientation of the substrate during the immersing, 411, can be controlled. Both the orientation of pattern to a liquid surface (i.e., facing or away) and the angle of entry can be varied. In some embodiments, the angle of entry, φ, is about 0° (i.e., a plane of the substrate is about co-planar with the plane of the liquid) to about 90° (i.e., a plane of the substrate is about perpendicular with the plane of the liquid), about 0° to about 70°, about 0° to about 45°, about 0° to about 30°, or about 0° to about 15°.

Surface features can be formed on articles using a process of the present invention such as, but not limited to, consumer electronics, industrial electronics, substrates containing integrated circuits, digital memory devices, display devices (e.g., plasma and liquid crystal displays), communication devices (e.g., phones, wireless systems, and the like), photovoltaic devices (e.g., solar cells and the like), jewelry, watches, textiles, optics and optical systems, space applications, military applications, architectural glass, medical devices, automobiles and automotive parts, and the like.

Exemplary articles, objects and devices comprising the patterned substrates prepared by a process of the present invention include, but are not limited to, windows; mirrors; optical elements (e.g., optical elements for use in eyeglasses, cameras, binoculars, telescopes, and the like); lenses (e.g., fresnel lenses, etc.); watch crystals; optical fibers, output couplers, input couplers, microscope slides, holograms; cathode ray tube devices (e.g., computer and television screens); optical filters; data storage devices (e.g., compact discs. DVD discs, CD-ROM discs, and the like); flat panel electronic displays (e.g., LCDs, plasma displays, and the like); touch-screen displays (such as those of computer touch screens and personal data assistants); solar cells; flexible electronic displays (e.g., electronic paper and books); cellular phones; global positioning systems; calculators; graphic articles signage); motor vehicles (e.g., wind screens, windows, displays, and the like); artwork (e.g., sculptures, paintings, lithographs, and the like); membrane switches; jewelry; and combinations thereof.

In some embodiments, the present invention is directed to a process for patterning an unmasked substrate, the process comprising:
(a) providing an unmasked substrate;
(b) depositing onto the unmasked substrate a pattern comprising a hydrophobic monolayer, wherein the pattern is produced by a microcontact printing process;
(c) optionally backfilling the areas of the substrate substantially not covered by the pattern with a composition comprising a hydrophilic material;
(d) disposing onto the substrate a hydrophobic composition, wherein the composition deposits preferentially on the pattern to form an amplified pattern, and wherein an area of the substrate not covered by the pattern is substantially free from the hydrophobic composition; and
(e) reacting the area of the substrate substantially free from the amplified pattern to form a surface feature thereon; and
(f) optionally rinsing the substrate with a solvent suitable for removing the amplified pattern comprising the hydrophobic monolayer and the hydrophobic composition deposited thereon.

### Apparatus for Patterning a Substrate

The present invention is also directed to an apparatus for patterning an unmasked substrate, the apparatus comprising:
(a) a means for preferentially depositing a composition onto a patterned substrate; and
(b) a means for reacting an area of the substrate substantially not covered by the pattern or the composition deposited thereon.

As used herein, “preferentially depositing” refers to a deposition process :in which a composition deposits onto an area of a substrate having a pattern thereon, while an unpatterned area of a substrate is not substantially covered by the composition, wherein no physical masking, shadow masking, metal masking, photo-masking or any other type of masking scheme is used (i.e., the patterned substrate is “unmasked”).

As used herein, a means for preferentially depositing a composition onto a patterned substrate can include a dip-coating means, a stamping means, a spin-coating means, a spray coating means, a powder coating means, a chemical vapor depositing means, a plasma depositing means, and a photo-assisted depositing means. For example, the present invention contemplates the use of a spin-coating and/or a dip-coating means for preferentially depositing a composition onto a patterned rigid or semi-rigid substrate. In some embodiments, a means for preferentially depositing can comprise a dip-coating means for depositing a composition onto a pattern comprising a self-assembled monolayer.

In some embodiments, the apparatus of the present invention further comprises a means for depositing onto an unmasked substrate a pattern comprising a self-assembled monolayer. As used herein, a means for depositing a self-assembled monolayer onto an unmasked substrate can include a microcontact printing means, a screen-printing means, a stenciling means, a syringe deposition means, an ink-jet printing means, a dip-pen nanolithography means, and combinations thereof. In some embodiments, the means for depositing a pattern comprising a self-assembled monolayer onto an unmasked substrate comprises a microcontact printing means.

In some embodiments, the apparatus of the present invention further comprises a means for providing the substrate; a means for transferring the substrate between the means for depositing the pattern and the means for reacting; and a means for collecting the substrate after reacting an area of the substrate.

As used herein, a “means for providing the substrate” and a “means for transferring the substrate between the for depositing the pattern and the means for reacting” can include a robotic arm, a supply reel (as part of a reel-to-reel process), a carousel, an elevator, a conveyor belt, a roller assembly, a liquid stream, a vacuum handler, and combinations thereof.

As used herein, a “means for collecting the substrate after reacting an area of the substrate” can include a robotic arm, a collection reel (as part of a reel-to-reel process), a carousel, an elevator, a conveyor belt, a roller assembly, a liquid stream, a vacuum handler, a tray, and combinations thereof.

In view of the above description and the examples below, one of ordinary skill in the art will be able to practice the invention as claimed without undue experimentation. The foregoing will be better understood with reference to the following examples that detail certain procedures for the preparation of compositions and formulations according to the present invention. All references made to these examples are for the purposes of illustration. The following examples should not be considered exhaustive, but merely illustrative of only a few of the many embodiments contemplated by the present invention.

### EXAMPLES

### Example 1

An Unmasked substrate (Au on glass) was patterned with a first material (hexadecane thiol) using state of the art conditions, as described, in, for example, U.S. Pat. No. 5,512,131, to form a pattern having a hydrophobic surface characteristic. The patterned, unmasked substrate was then immersed for about 1 minute in a solution of a second material having a hydrophilic surface characteristic (11-mercaptoundecanoic acid). The second material deposited on the unpatterned areas of the substrate. The patterned, unmasked substrate was then rinsed with ethanol and dried for 1 minute under dry nitrogen. A Petri dish containing a first layer of 20 mL of DI water and a second layer of 400 μL of hexadecane was prepared. The substrate was placed into the Petri dish until it was immersed completely in the water layer for about 1 minute. The substrate was then removed from the Petri dish and dried under nitrogen. Images of the resulting amplified pattern are displayed FIG. 5A-5C. The images show the substrate, 500, and amplified patterns, 501. Notice that in certain areas the amplification of the pattern is not completely uniform, 502 (indicated by dashed lines, “- - - - ”), resulting in patterns that are not completely covered, sharp corners that lack complete coverage, and wetting of certain hydrophilic areas of the substrate. FIG. 5B provides a magnification of one of the amplified patterns in FIG. 5A. FIG. 5C provides a magnification of the inset region of FIG. 5B, 503. The image provides an example of the rounding of the pattern edges, 504, that can occur when as pattern comprises a sharp corner. In some embodiments, when a composition having a hydrophobic surface characteristic is disposed preferentially onto a pattern, the use a molecular species having a lower molecular weight and/or shorter chain (i.e., alkyl chain having a reduced number of carbon atoms) can reduce the “rounding” of features.

### Example 2

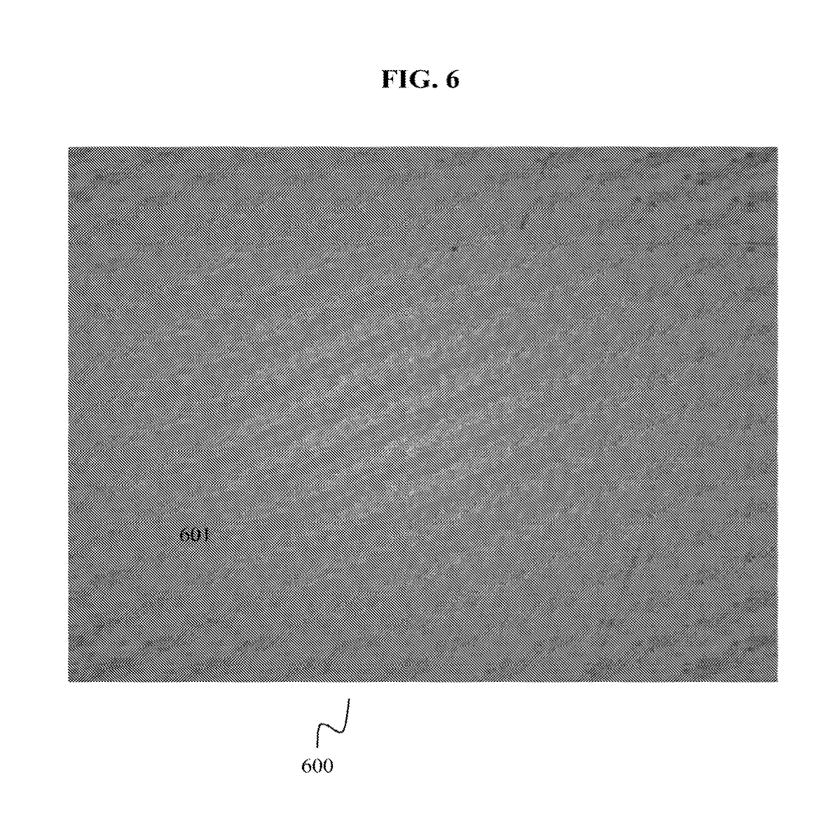

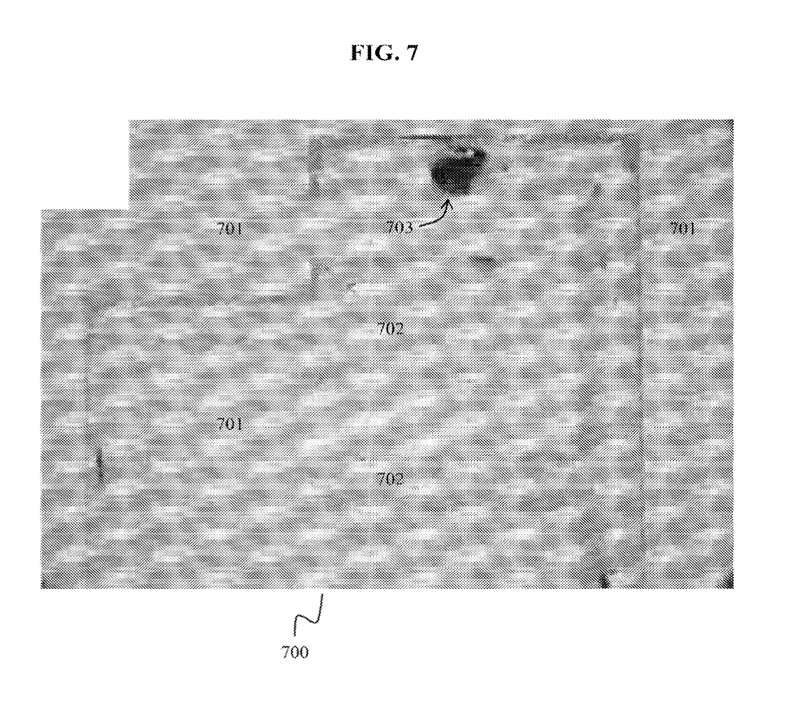

Unmasked substrates (Au on glass) were patterned with a hydrophobic first material (hexadecane thiol) and then back-filled with a second hydrophilic material (50 mM ethanolic bis(2-hydroxyethyl disulfide)). The patterned, unmasked substrates were then exposed to a liquid etchant without amplification of the pattern. Images of the resulting substrates are provided in FIG. 6 and FIG. 7. The etching conditions were as follows: a wet etchant (containing KI- or KCN-containing etchant) was placed in a vessel (50 mL beaker) and the unmasked substrates were immersed in the etch solution for 10 seconds. Table 1 lists the process parameters for the substrates shown in FIG. 6 and FIG. 7.

TABLE 1
Process parameters used to produce surface features
without amplification of a pattern.

| Sample | Amplification Layer | Etchant | Etch Time (sec) |
|---|---|---|---|
| 6 | none | KI | 10 |
| 7 | none | KCN | 10 |
| | | (Technistrip ™ RTU^{a}) | |

^{a}Technic, Inc., Providence, RI.

FIG. 6 provides a transmission image of a patterned substrate (Au on glass) dipped in a KI etch bath for 10 seconds. FIG. 6 shows that both the pattern and the Au layer were completely removed from the glass substrate by the KI etch solution. Thus, under these conditions the unamplified pattern does not provide a method to form a subtractive surface feature.

FIG. 7 provides a transmission image of patterned substrate dipped in Technistrip™ RTU (Technic, Inc., Providence, R.I.) for 10 s. FIG. 7 again shows that the unamplified pattern was largely ineffective for protecting the Au surface from the KCN etchant solution. The substrate, 700, contains unpatterned areas, 701, and patterned areas, 702. However, patterned areas of the gold surface were partially etched by the KCN etchant. The dark areas in the image, 703, show those areas that were etched to a lesser degree by the etchant. Thus, under these conditions the unamplified pattern does not provide a method to form a subtractive surface feature.

### Example 3

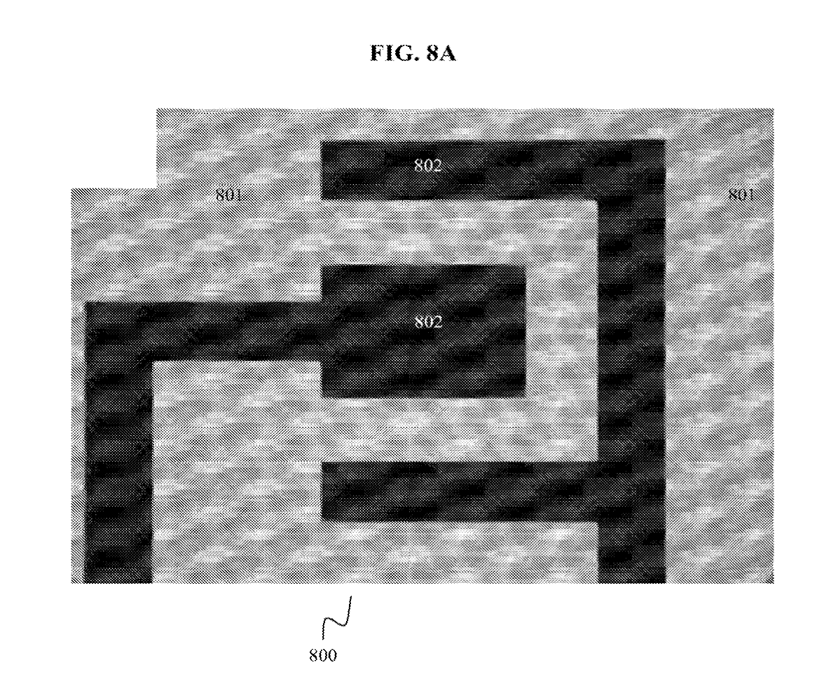

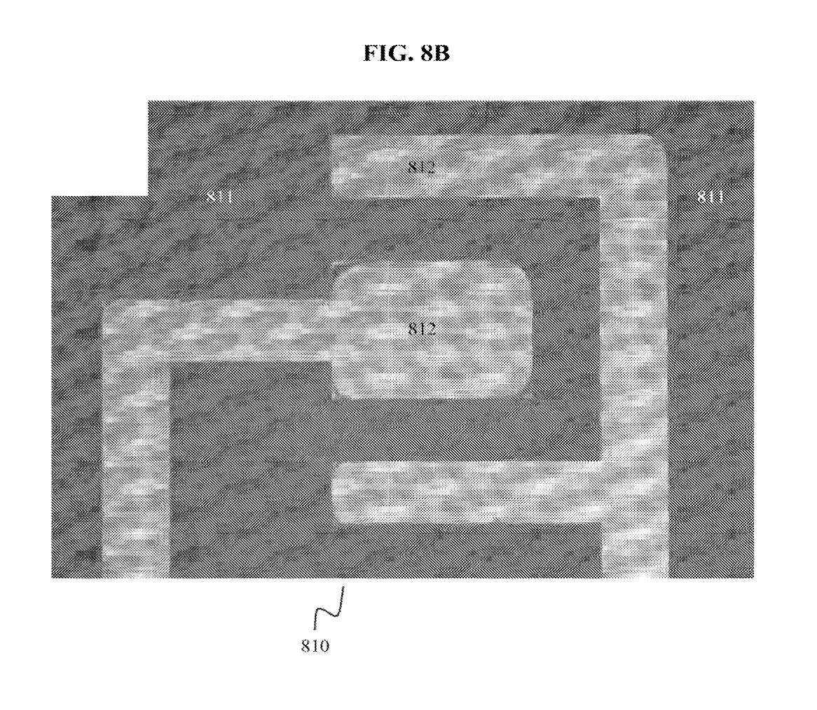

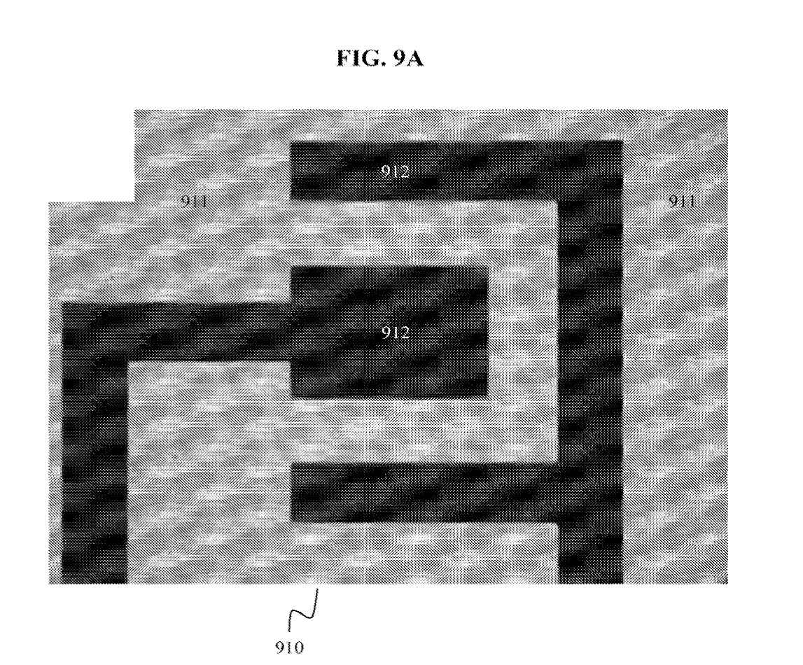

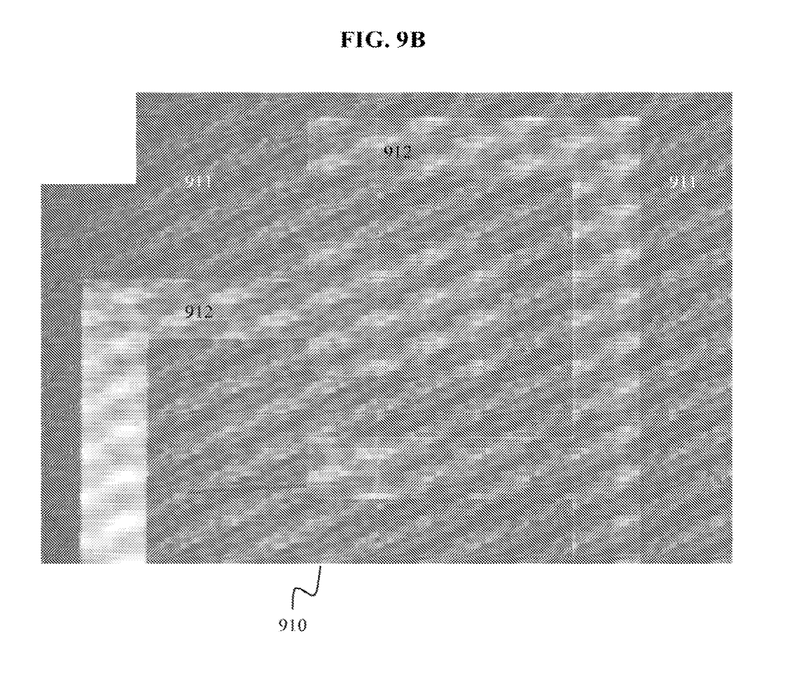

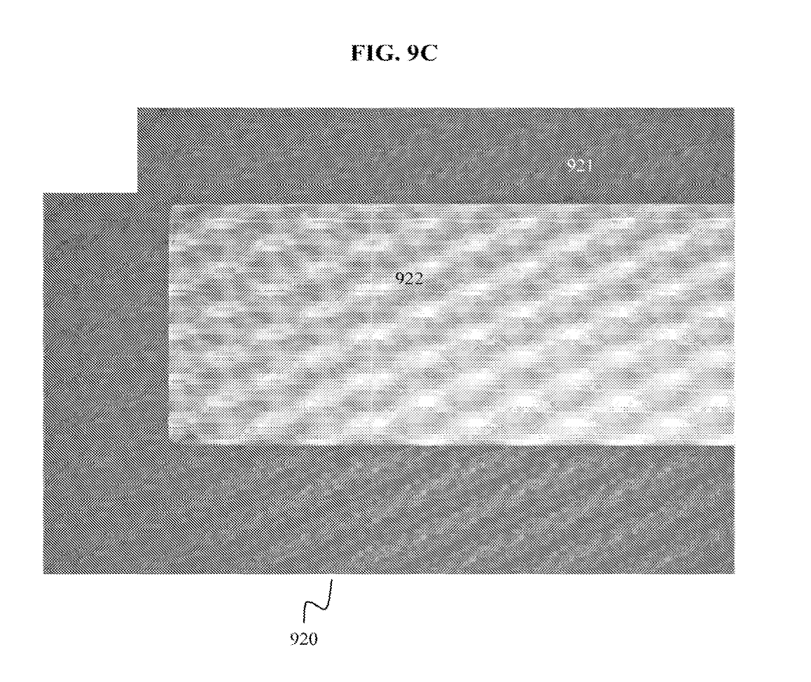

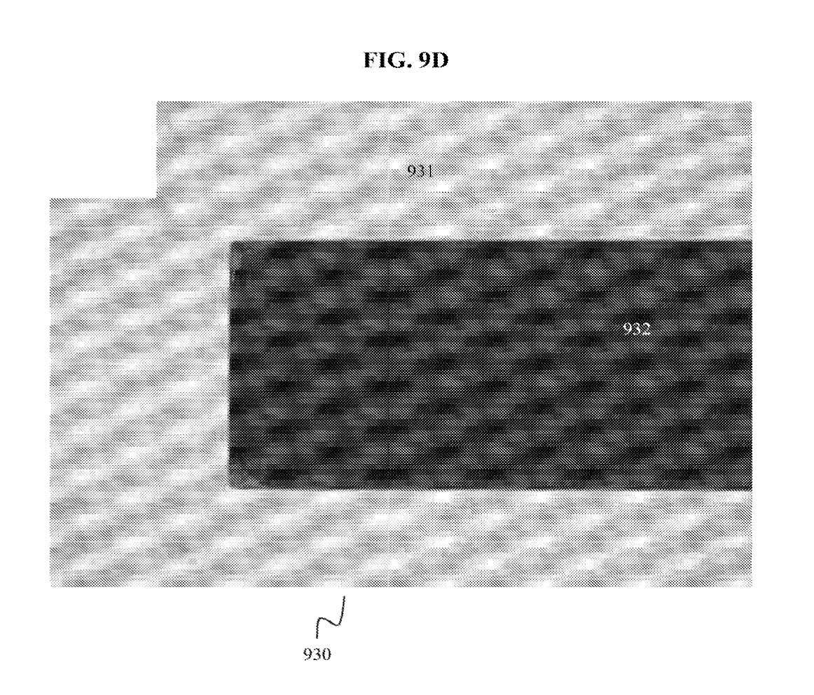

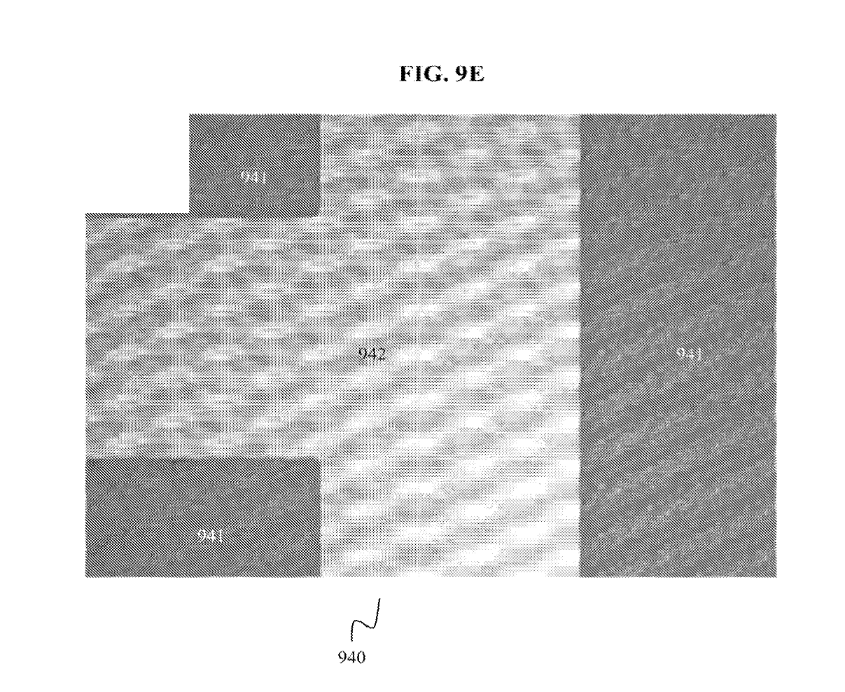

Unmasked substrates (Au on glass) were patterned with a hydrophobic first material (hexadecane thiol) and then back-filled with a second hydrophilic material (50 mM ethanolic bis(2-hydroxyethyl disulfide)). The patterns on the unmasked substrates were then amplified by passing through a hexadecane layer immediately prior to entering an etching solution. Images of the resulting substrates are provided in FIGS. 8A and 8B and. FIGS. 9A, 9B, 9C, 9D and 9E. The patterning conditions were as follows: a wet etchant KI-containing etchant for the substrate in FIGS. 8A and 8B and a KCN-containing etchant for the substrate in FIGS. 9A, 9B, 9C, 9D and 9E) was placed in a vessel (50 mL beaker), and a hydrophobic composition (hexadecane, 200 μL) was placed on the surface of the liquid etchant. The patterned, unmasked substrates provided in (identical to those used in Example 2) were passed through the hydrophobic composition prior to entering the etchant. Table 2 describes the process parameters for the substrates shown in FIGS. 8A and 8B and FIGS. 9A, 9B, 9C, 9D and 9E.

TABLE 2
Process parameters used to produce surface features
following amplification of a pattern.

| | Amplification | | |
|---|---|---|---|
| Sample | Layer | Etchant | Etch Time (sec) |
| 8A, 8B | hexadecane | KI | 10 |
| 9A, 9B, 9C, 9D, 9E | hexadecane | KCN | 10 |
| | | (Technistrip ™ | |
| | | RTU) | |

FIGS. 8A and 8B provide transmission and DIC images, respectively, of a patterned substrate immersed for 10 seconds in a KI etchant after passing through a layer of hexadecane (200 μL). Comparison of FIGS. 8A and 8B with FIG. 6 shows that amplification of the pattern is necessary for formation of a surface feature on the substrate.

FIGS. 9A and 9B provide transmission and DIC images, respectively, of a patterned substrate immersed for 10 seconds in KCN etchant (Technistrip™ RTU) after passing through a layer of hexadecane (200 μL). Comparison of FIGS. 9A and 9B with FIG. 7 shows that a uniform surface feature is formed when the pattern is amplified prior to reacting. For example, the pattern formed after amplification of the pattern (i.e., FIGS. 9A and 9B) is uniform over its entire area.

FIGS. 9C, 9D and 9E provide high magnification DIC and transmission images of the patterned substrate shown in FIGS. 9A and 9B.

### Example 4

Patterned, unmasked substrates (Au on glass patterned with hexadecanethiol processed under SOTA conditions: ink time: 20 seconds, stamp time: 15 seconds) were amplified with hexadecane and etched with a KI- or KCN-containing etchant. The lateral dimensions of the surface features were measured, the results of which are listed in Table 3.

TABLE 3
Quality metrics for samples prepared with SAM amplification.
Note that pinhole density and pinhole area are zero (0).

| | | | Pinhole | | |
|---|---|---|---|---|---|
| | | Selectivity | area | Pinhole | Deviation from target |
| Sample | Etchant | (%) | (%) | Density | specs (μm)^{a} |
| 1 | KI | 0.996 | 0.00 | 0 | 5.424 |
| 2 | KCN | 0.938 | 0.00 | 0 | 5.537 |

^{a}The deviation from target dimensions does not take into account the rounded corners of the surface features.

As used herein, selectivity refers to the intensity of transmitted light through the gold features after etching (I_{ETCHED}) by the intensity of transmitted light through the native substrate (I_{ZERO}), Selectivity=I_{ETCHED}/I_{ZERO}.

As used herein, pinhole area (%) refers to the summed area of all pinholes present in a pattern divided by the pattern area.

As used herein, pinhole density refers to the number of pinholes per pattern area.

As used herein., deviation from target specifications refers to the width of an actual surface feature minus the target width, Deviation=Width_{ACTUAL}−Width_{TARGET}.

### CONCLUSION

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described, exemplary embodiments, but should be defined only in accordance with the following claims and their equivalents.

It is to be appreciated that the Detailed Description section, and not the Summary and Abstract sections, is intended to be used to interpret the claims. The Summary and Abstract sections can set forth one or more, but not all exemplary embodiments of the present invention as contemplated by the inventor(s), and thus, are not intended to limit the present invention and the appended claims in any way.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

What is claimed.

1. A process for patterning an unmasked substrate, the process comprising:
(a) providing an unmasked substrate;
(b) depositing onto the unmasked substrate a pattern comprising a first material having a first surface characteristic, wherein the pattern substantially covers a first area of the unmasked substrate;
(c) disposing onto the unmasked substrate a composition having a functional group suitable for associating with the surface of the pattern, wherein the composition deposits preferentially onto the pattern to form an amplified pattern, and wherein an area of the unmasked substrate not covered by the pattern is substantially free from the composition; and
(d) reacting the area of the unmasked substrate not covered by the amplified pattern to form a surface feature thereon, wherein the first area of the substrate covered by the amplified pattern is substantially not reacted.

2. The process of claim 1, further comprising prior to (d): depositing onto the substrate a second pattern comprising a second material having a second surface characteristic, wherein the second surface characteristic is different from the first surface characteristic of the first material, and wherein the second pattern substantially covers a second area of the substrate.

3. The process of claim 1, further comprising after (b): disposing onto the substrate a second material having a second surface characteristic that is different from the first surface characteristic, wherein the second composition deposits preferentially on an area of the substrate not covered by the pattern.

4. The process of claim 1, wherein the reacting comprises at least one of: wet etching, dry etching, electroplating, cleaning, chemically oxidizing, chemically reducing, exposing to ultraviolet light, and combinations thereof.

5. The process of claim 4, wherein the reacting is wet etching.

6. The process of claim 1, further comprising after solidifying the amplified pattern.

7. The process of claim 1, further comprising after (d): removing the amplified pattern from the substrate.

8. The process of claim 1, wherein the providing comprises providing a substrate selected from a metal, a metal oxide, a glass, a semiconductor, a plastic, a laminate thereof, and combinations thereof.

9. The process of claim 1, wherein the depositing comprises depositing a pattern comprising a self-assembled monolayer.

10. The process of claim 9, wherein the depositing comprises depositing a pattern comprising a self-assembled monolayer by a microcontact printing process.

11. The process of claim 1, wherein the depositing further comprises depositing a first self-assembled monolayer having a hydrophobic surface characteristic.

12. The process of claim 1, wherein the disposing comprises a composition that includes a compound having two or more functional groups suitable for associating with the surface of the pattern.

13. The process of claim 1, wherein the disposing comprises a composition that includes a compound lacking a C—F bond or a Si—F bond.

14. The process of claim 1, wherein the reacting is for a time period of about 1 minute or less.

15. The process of claim 1, wherein the depositing and the disposing occur over a total of about 1 minute or less.

16. The process of claim 1, wherein the providing comprises a laminate substrate that includes a gold layer over a plastic or glass underlayer; wherein the depositing comprises microcontact printing a first material that includes hexadecane thiol onto the gold layer; wherein the disposing comprises a composition that includes hexadecane; and wherein the reacting comprises wet etching, the gold layer.

17. The process of claim 16, further comprising after (b) and prior to (c): disposing onto the substrate a second material having a hydrophilic surface characteristic, wherein the second composition deposits preferentially on an area of the substrate not covered by the pattern.

18. A process for increasing the reaction selectivity between a patterned area of a substrate and an unpatterned area of a substrate, the process comprising:
(a) providing a substrate having a pattern formed thereon, wherein the pattern comprises a material having a first surface characteristic, wherein the pattern substantially covers a first area of the substrate;
(b) disposing onto the substrate a composition that deposits preferentially on the pattern via a covalent bonding interaction to form an amplified pattern, wherein an area of the substrate not covered by the pattern is substantially free from, the composition, wherein the area of the substrate covered by the amplified pattern has a reactivity with a reactant that is at least three times less than the reactivity of an area of the substrate having the unamplified pattern thereon; and
(c) reacting the area of the substrate not covered by the pattern to form a surface feature thereon.

19. The process of claim 18, wherein during the reacting, the area of the substrate not covered by the pattern reacts at least about five times faster than the area of the substrate covered by the amplified pattern.

20. The process of claim 18, wherein the reacting is for a time period of about 1 minute or less.
